(19) United States
(12) Patent Application Publication
(10) Pub. No.: US 2023/0408692 A1
(43) Pub. Date: Dec. 21, 2023

(54) DISTANCE MEASURING SENSOR AND DISTANCE MEASURING SYSTEM

(71) Applicant: SONY SEMICONDUCTOR SOLUTIONS CORPORATION, KANAGAWA (JP)

(72) Inventor: KUMIKO MAHARA, KANAGAWA (JP)

(21) Appl. No.: 18/250,759

(22) PCT Filed: Oct. 25, 2021
(86) PCT No.: PCT/JP2021/039303

§ 371 Date: Apr. 27, 2023

(30) Foreign Application Priority Data
Nov. 5, 2020 (JP) 2020-184890

(51) Int. Cl. G01S 17/14; H01L 31/107; G01S 17/894; G01S 7/4865

(52) U.S. Cl. CPC G01S 17/14; H01L 31/107; G01S 17/894; G01S 7/4865

(57) ABSTRACT

The present technology relates to a distance measuring sensor and a distance measuring system capable of performing different measurements using SPAD pixels. The distance measuring sensor includes a single photon avalanche diode (SPAD) pixel including a SPAD as a photoelectric conversion element, a time-of-flight (ToF) data processing unit that generates and outputs distance measurement data by a ToF method on the basis of a pixel signal output from the SPAD pixel, and a viewing data processing unit that generates and outputs viewing data on the basis of a pixel signal output from the SPAD pixel. The present technology can be applied to, for example, a distance measuring system that measures a distance to a subject, and the like.

### TECHNICAL FIELD

The present technology relates to a distance measuring sensor and a distance measuring system, and more particularly relates to a distance measuring sensor and a distance measuring system capable of performing different measurements using SPAD pixels.

### BACKGROUND ART

In recent years, a distance measuring sensor that measures a distance by a time-of-flight (ToF) method has attracted attention. The distance measuring sensor includes a direct ToF method and an indirect ToF method. The indirect ToF method is a method of detecting a flight time from a timing at which irradiation light is emitted to a timing at which reflected light is received as a phase difference and calculating a distance to an object, and can achieve measurement in a relatively short distance range with high accuracy. On the other hand, the direct ToF method is a method of calculating the distance to the object by directly measuring the flight time from the timing at which the irradiation light is emitted to the timing at which the reflected light is received, and is more effective for measuring a farther distance than the indirect ToF method. For example, Patent Document 1 discloses a distance measuring sensor of the direct ToF method. Furthermore, Patent Document 2 discloses a distance measuring sensor of the indirect ToF method.

In the direct ToF distance measuring sensor, for example, a single photon avalanche diode (SPAD) is used as a light receiving pixel. In the SPAD, avalanche amplification occurs when one photon enters a PN junction region of a high electric field in a state where a voltage larger than the breakdown voltage is applied. By detecting the timing at which the current instantaneously flows at that time, the distance can be measured with high accuracy.

### CITATION LIST

### Patent Document

Patent Document 1: WO 2018/074530
Patent Document 2: Japanese Patent Application Laid-Open No. 2011-86904

### SUMMARY OF THE INVENTION

### Problems to be Solved by the Invention

In configuring the distance measurement device, by using a plurality of distance measuring sensors having different distance measurement methods, it is possible to cover a wide distance measurement range and improve distance measurement accuracy.

However, for example, if distance measuring sensors of different systems are simply combined, the device scale increases and the cost increases.

The present disclosure has been made in view of such a situation, and in particular, enables different measurements to be performed using SPAD pixels.

### Solutions to Problems

A distance measuring sensor according to a first aspect of the present technology includes a single photon avalanche diode (SPAD) pixel including a SPAD as a photoelectric conversion element, a time-of-flight (ToF) data processing unit that generates and outputs distance measurement data by a ToF method on the basis of a pixel signal output from the SPAD pixel, and a viewing data processing unit that generates and outputs viewing data on the basis of a pixel signal output from the SPAD pixel.

A distance measuring system according to a second aspect of the present technology includes a light emitting unit that emits irradiation light, a distance measuring sensor that receives reflected light in which the irradiation light is reflected by an object, in which the distance measuring sensor includes a single photon avalanche diode (SPAD) pixel including a SPAD as a photoelectric conversion element, a time-of-flight (ToF) data processing unit that generates and outputs distance measurement data by a ToF method on the basis of a pixel signal output from the SPAD pixel, and a viewing data processing unit that generates and outputs viewing data on the basis of a pixel signal output from the SPAD pixel.

In the first and second aspects of the present technology, distance measurement data is generated and output by the ToF method on the basis of a pixel signal output from the SPAD pixel including a SPAD as a photoelectric conversion element, and viewing data is generated and output on the basis of a pixel signal output from the SPAD pixel.

The distance measuring sensor and the distance measuring system may be independent devices or modules incorporated in other devices.

### BRIEF DESCRIPTION OF DRAWINGS

FIG. 1 is a block diagram illustrating a configuration example of an embodiment of a distance measuring system to which the present technology is applied.

FIG. 2 is a block diagram illustrating a first configuration example of a first embodiment of a distance measuring sensor.

FIG. 3 is a block diagram illustrating a first modification of the distance measuring sensor according to the first configuration example.

FIG. 4 is a block diagram illustrating a second modification of the distance measuring sensor according to the first configuration example.

FIG. 5 is a diagram illustrating a circuit configuration example that can be employed as a SPAD pixel of a SPAD pixel array unit.

FIG. 6 is a diagram illustrating an operation of the SPAD pixel in FIG. 5.

FIG. 7 is a diagram illustrating a principle of dToF distance measurement.

FIG. 8 is a diagram illustrating a principle of iToF distance measurement.

FIG. 9 is a diagram illustrating processing of a dToF data processing unit.

FIG. 10 is a diagram illustrating processing of an iToF data processing unit.

FIG. 11 is a diagram illustrating processing of a viewing data processing unit.

FIG. 12 is a timing chart illustrating an operation of the light emission timing control section.

FIG. 13 is a block diagram illustrating a second configuration example of the first embodiment of the distance measuring sensor.

FIG. 14 is a diagram illustrating an operation of a high-speed sampling circuit.

FIG. 15 is a diagram illustrating an operation of the high-speed sampling circuit.

FIG. 16 is a diagram illustrating a first configuration example of the high-speed sampling circuit.

FIG. 17 is a time chart illustrating processing of the high-speed sampling circuit in a dToF distance measurement mode.

FIG. 18 is a diagram illustrating processing of the dToF data processing unit in the dToF distance measurement mode.

FIG. 19 is a diagram illustrating processing in an iToF distance measurement mode.

FIG. 20 is a diagram illustrating processing in a viewing mode.

FIG. 21 is a diagram illustrating a second configuration example of the high-speed sampling circuit.

FIG. 22 is a time chart illustrating high-speed sampling processing in the dToF distance measurement mode.

FIG. 23 is a diagram illustrating an example in which a high-speed counter circuit is shared.

FIG. 24 is a block diagram illustrating a first configuration example of a second embodiment of the distance measuring sensor.

FIG. 25 is a diagram illustrating an example of a color filter layer provided in a SPAD pixel array unit.

FIG. 26 is a diagram illustrating a peak period of histogram data.

FIG. 27 is a diagram illustrating generation of a count mask signal.

FIG. 28 is a block diagram illustrating a schematic configuration of a counting circuit.

FIG. 29 is a block diagram illustrating a modification of the first configuration example according to the second embodiment.

FIG. 30 is a block diagram illustrating a second configuration example of the second embodiment of the distance measuring sensor.

FIG. 31 is a diagram illustrating processing of a peak section signal and a histogram counting circuit.

FIG. 32 is a block diagram illustrating a configuration example of a smartphone in which the distance measuring system in FIG. 1 is mounted as a distance measuring module.

FIG. 33 is a block diagram illustrating an example of a schematic configuration of a vehicle control system.

FIG. 34 is a diagram of assistance in explaining an example of installation positions of an outside-vehicle information detecting section and an imaging section.

### MODE FOR CARRYING OUT THE INVENTION

Hereinafter, modes for carrying out the present technology (hereinafter referred to as an embodiment) will be described with reference to the accompanying drawings. Note that in the description and the drawings, components having substantially the same function and configuration are denoted by the same reference numerals, and redundant descriptions are omitted. The description will be made in the following order.
1. Configuration example of distance measuring system
2. First configuration example of first embodiment of distance measuring sensor
3. Description of SPAD pixel
4. Processing in each measurement mode using SPAD pixel
5. Operation of light emission timing control section
6. Second configuration example of first embodiment of distance measuring sensor
7. Operation of high-speed sampling circuit
8. First configuration example of high-speed sampling circuit
9. High-speed sampling processing in dToF distance measurement mode
10. dToF data processing of dToF data processing unit
11. Processing in iToF distance measurement mode
12. Processing in viewing mode
13. Second configuration example of high-speed sampling circuit
14. High-speed sampling processing in dToF distance measurement mode
15. Summary of first embodiment
16. First configuration example of second embodiment of distance measuring sensor
17. Generate count mask signal
18. Modification of first configuration example of second embodiment
19. Second configuration example of second embodiment of distance measuring sensor
20. Summary of second embodiment
21. Configuration example of electronic device
22. Application example to mobile body

### 1. Configuration Example of Distance Measuring System

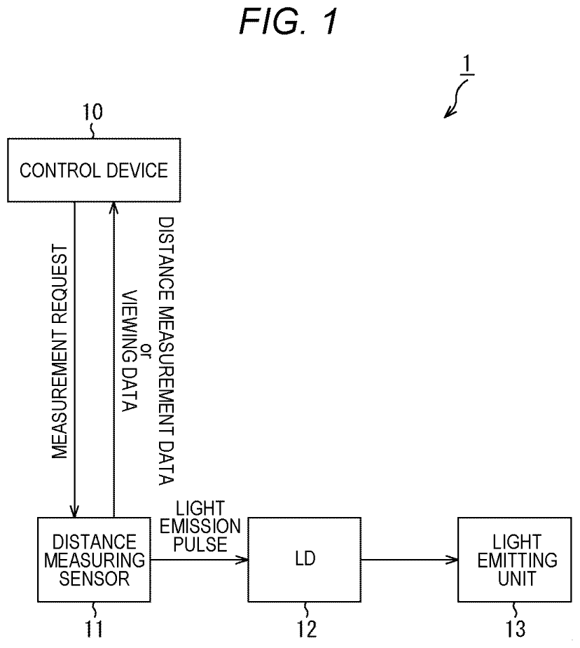

FIG. 1 is a block diagram illustrating a configuration example of a distance measuring system of the present disclosure.

The distance measuring system 1 in FIG. 1 includes a control device 10, a distance measuring sensor 11, an LD 12, and a light emitting unit 13.

The control device 10 is a device that controls the distance measuring sensor 11. For example, the control device 10 designates a predetermined measurement method on the basis of a command from a host device of a higher level, and supplies a measurement request for requesting execution of measurement to the distance measuring sensor 11. The measurement method specified here is any of distance measurement by the direct ToF method, distance measurement by the indirect ToF method, or viewing measurement.

The distance measurement by the indirect ToF method is distance measurement including detecting a flight time from a timing at which irradiation light is emitted to a timing at which reflected light is received as a phase difference and calculating a distance to an object, and can achieve measurement in a relatively short distance range with high accuracy. The direct ToF method is a distance measurement for calculating the distance to the object by directly measuring the flight time from the timing at which the irradiation light is emitted to the timing at which the reflected light is received, and is more effective for measuring a farther distance than the indirect ToF method. The viewing measurement is a measurement that outputs luminance data according to a received light amount like a general image sensor. Hereinafter, for simplicity, the direct ToF method is referred to as dToF, the indirect ToF method is referred to as iToF, distance measurement by the direct ToF method is referred to as dToF distance measurement, and distance measurement by the indirect ToF method is referred to as iToF distance measurement.

Note that the control device 10 can supply a measurement request to the distance measuring sensor 11 without specifying a measurement method, and the distance measuring sensor 11 can execute the three measurement methods in a predetermined order and output a measurement result to the control device 10.

The control device 10 acquires distance measurement data or viewing data, which is a result of measurement executed by the distance measuring sensor 11 in response to the measurement request, from the distance measuring sensor 11.

In response to the measurement request from the control device 10, the distance measuring sensor 11 executes measurement by the designated measurement method, and outputs distance measurement data or viewing data, which is a result of the measurement, to the control device 10. The distance measuring sensor 11 is a sensor including a single photon avalanche diode (SPAD) as a photoelectric conversion element for light reception in each pixel.

At the time of measurement, the distance measuring sensor 11 controls the light emitting unit 13 as necessary to emit irradiation light. When the irradiation light is emitted, the distance measuring sensor 11 supplies a predetermined light emission pulse to the LD 12. The LD 12 is a laser driver that drives the light emitting unit 13, drives the light emitting unit 13 on the basis of the light emission pulse from the distance measuring sensor 11, and causes the light emitting unit 13 to output the irradiation light. The light emitting unit 13 includes, for example, a vertical cavity surface emitting laser LED (VCSEL) or the like, and emits irradiation light by driving the LD 12. As the irradiation light, for example, infrared light (IR light) having a wavelength in a range of about 850 nm to 940 nm is used.

### 2. First Configuration Example of First Embodiment of Distance Measuring Sensor

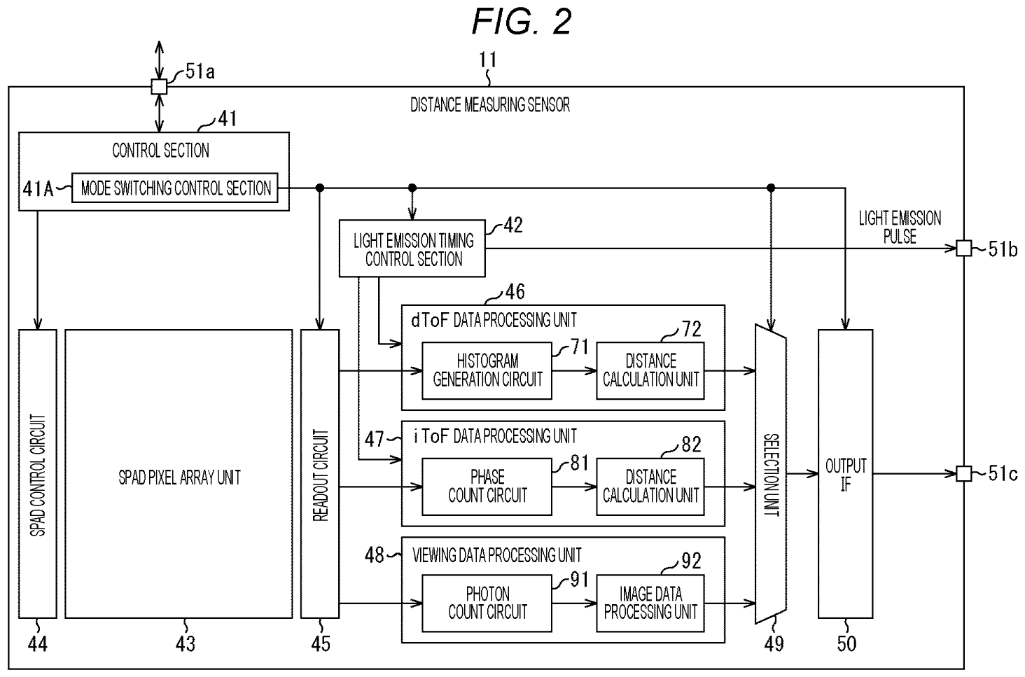

FIG. 2 is a block diagram illustrating a first configuration example of the first embodiment of the distance measuring sensor 11.

The distance measuring sensor 11 includes a control section 41, a light emission timing control section 42, a SPAD pixel array unit 43, a SPAD control circuit 44, a readout circuit 45, a dToF data processing unit 46, an iToF data processing unit 47, a viewing data processing unit 48, a selection unit 49, an output IF 50, and input-output terminals 51a to 51c.

The control section 41 controls the entire operation of the distance measuring sensor 11. For example, the control section 41 performs predetermined communication such as reception of the measurement request and transmission of the distance measurement data, viewing data, or the like with the control device 10. The control section 41 includes a mode switching control section 41A, and switches the measurement mode of the distance measuring sensor 11 on the basis of the measurement method designated by the control device 10. The mode switching control section 41A supplies any one of the dToF distance measurement mode, the iToF distance measurement mode, or the viewing mode to the readout circuit 45, the light emission timing control section 42, the selection unit 49, and the output IF 50 as the measurement mode to be executed.

The dToF data processing unit 46 includes a histogram generation circuit 71 and a distance calculation unit 72, and generates and outputs distance measurement data by dToF distance measurement in the dToF distance measurement mode. The iToF data processing unit 47 includes a phase counting circuit 81 and a distance calculation unit 82, and generates and outputs distance measurement data by iToF distance measurement in the iToF distance measurement mode. The viewing data processing unit 48 includes a photon counting circuit 91 and an image data processing unit 92, and generates and outputs viewing data in a viewing mode.

When performing measurement in any of the dToF distance measurement mode, the iToF distance measurement mode, or the viewing mode, the distance measuring sensor 11 can operate all the SPAD pixels in the SPAD pixel array unit 43 (active pixels to be described later) or can operate only some SPAD pixels of a plurality of lines or the like. The control section 41 supplies an active control signal for controlling which SPAD pixel in the SPAD pixel array unit 43 is operated to the SPAD control circuit 44.

Under control of the mode switching control section 41A, the light emission timing control section 42 generates a light emission pulse for controlling the light emission timing of the irradiation light for the dToF distance measurement or the iToF distance measurement, and outputs the light emission pulse to the LD 12 via the input-output terminal 51b. Furthermore, the light emission timing control section 42 also supplies the generated light emission pulse to the dToF data processing unit 46 and the iToF data processing unit 47.

The SPAD pixel array unit 43 includes a plurality of SPAD pixels two-dimensionally arranged in a matrix, and supplies a pixel signal corresponding to the reflected light detected by each SPAD pixel to the readout circuit 45. The SPAD pixel includes, for example, the single photon avalanche diode (SPAD) as a photoelectric conversion element. In the SPAD, avalanche amplification occurs when one photon enters a PN junction region of a high electric field in a state where a voltage larger than the breakdown voltage is applied. A timing at which the current instantaneously flows at that time is detected and output to the readout circuit 45 as a pixel signal. Note that, in the following description, the SPAD pixel may be simply referred to as a pixel for simplicity.

The SPAD control circuit 44 switches an active pixel or an inactive pixel for each SPAD pixel of the SPAD pixel array unit 43 on the basis of the active control signal supplied from the control section 41. The active pixel is a pixel that detects incidence of photons, and the inactive pixel is a pixel that does not detect incidence of photons. Therefore, the SPAD control circuit 44 controls on and off of the light receiving operation of each SPAD pixel of the SPAD pixel array unit 43. For example, the SPAD control circuit 44 performs control to set at least some of the plurality of SPAD pixels of the SPAD pixel array unit 43 as active pixels and the remaining SPAD pixels as inactive pixels at a predetermined timing in accordance with the light emission pulse from the light emission timing control section 42. Of course, all the SPAD pixels of the SPAD pixel array unit 43 may be the active pixels.

The readout circuit 45 supplies the pixel signal supplied from each SPAD pixel of the SPAD pixel array unit 43 to any one of the dToF data processing unit 46, the iToF data processing unit 47, or the viewing data processing unit 48 according to the measurement mode designated by the mode switching control section 41A. That is, in a case where the measurement mode designated by the mode switching control section 41A is the dToF distance measurement mode, the readout circuit 45 supplies the pixel signal supplied from each SPAD pixel to the dToF data processing unit 46. On the other hand, in a case where the designated measurement mode is the iToF distance measurement mode, the readout circuit 45 supplies the pixel signal supplied from each SPAD pixel to the iToF data processing unit 47. Alternatively, in a case where the specified measurement mode is the viewing mode, the readout circuit 45 supplies the pixel signal supplied from each SPAD pixel to the viewing data processing unit 48.

The histogram generation circuit 71 of the dToF data processing unit 46 creates a histogram of the flight time (count value) until the reflected light is received for each pixel on the basis of the emission of the irradiation light repeatedly executed a predetermined number of times (for example, several to several hundred times) and the reception of the reflected light. Data regarding the created histogram (hereinafter referred to as histogram data) is supplied to the distance calculation unit 72. The distance calculation unit 72 performs noise removal, histogram peak detection, and the like on the histogram data supplied from the histogram generation circuit 71. Then, the distance calculation unit 72 calculates the flight time until the light emitted from the light emitting unit 13 is reflected by the subject and returned on the basis of a detected peak value of the histogram, and calculates the distance to the subject for each pixel from the calculated flight time. The calculated distance measurement data is supplied to the selection unit 49.

Note that the histogram generation circuit 71 and the distance calculation unit 72 of the dToF data processing unit 46 can calculate the histogram data and calculate the distance to the subject based on the histogram data not in units of pixels but in units of a plurality of pixels.

The phase counting circuit 81 of the iToF data processing unit 47 counts the number of times of reception of the reflected light of each of the phase 0 degrees and the phase 180 degrees. More specifically, the phase counting circuit 81 measures the number of times of receiving the reflected light at the timing (phase 0 degrees) of the same phase as the light emission timing of the irradiation light and the number of times of receiving the reflected light at the timing (phase 180 degrees) of the phase obtained by inverting the light emission timing of the irradiation light, and supplies the numbers of times to the distance calculation unit 82. The distance calculation unit 82 calculates the distance to the subject for each pixel by detecting the phase difference of the reflected light with respect to the irradiation light on the basis of the ratio of the numbers of counts of the phase 0° and the phase 180°. The calculated distance measurement data is supplied to the selection unit 49. The iToF data processing unit 47 can also calculate the distance to the subject by counting the number of times of light reception at the phase of 0 degrees and the phase of 180 degrees not in units of pixels but in units of a plurality of pixels.

The photon counting circuit 91 of the viewing data processing unit 48 counts, for each pixel, the number of times the SPAD of each pixel in the SPAD pixel array unit 43 has reacted, that is, the number of times the photon is incident within a predetermined period. Then, the photon counting circuit 91 supplies a counting result to the image data processing unit 92. The image data processing unit 92 generates image data (viewing data) in which the counting result of photons measured in each pixel is set to a pixel value (luminance value) according to the received light amount, and supplies the image data to the selection unit 49. Also in the viewing data processing unit 48, the photon counting result can be performed not in units of pixels but in units of a plurality of pixels.

The selection unit 49 selects one of the dToF data processing unit 46, the iToF data processing unit 47, or the viewing data processing unit 48 according to the measurement mode designated by the mode switching control section 41A. The selection unit 49 supplies the distance measurement data or the viewing data output from the selected processing unit to the output IF 50.

The output IF 50 shapes the distance measurement data or the viewing data acquired via the selection unit 49 into a predetermined format corresponding to the data type, and then outputs the data to the control device 10 via the input-output terminal 51c.

The distance measuring sensor 11 has the above configuration, and controls light emission of irradiation light by the light emitting unit 13 in the measurement mode according to the designated measurement method, and generates and outputs distance measurement data or viewing data based on a result of light reception by the SPAD pixels of the SPAD pixel array unit 43.

As described above, in any of the measurement modes of the dToF distance measurement mode, the iToF distance measurement mode, and the viewing mode, it is possible to output the measurement result by aggregating not in units of one pixel but in units of a plurality of pixels, but in the following description, a case of performing in units of one pixel will be described as an example.

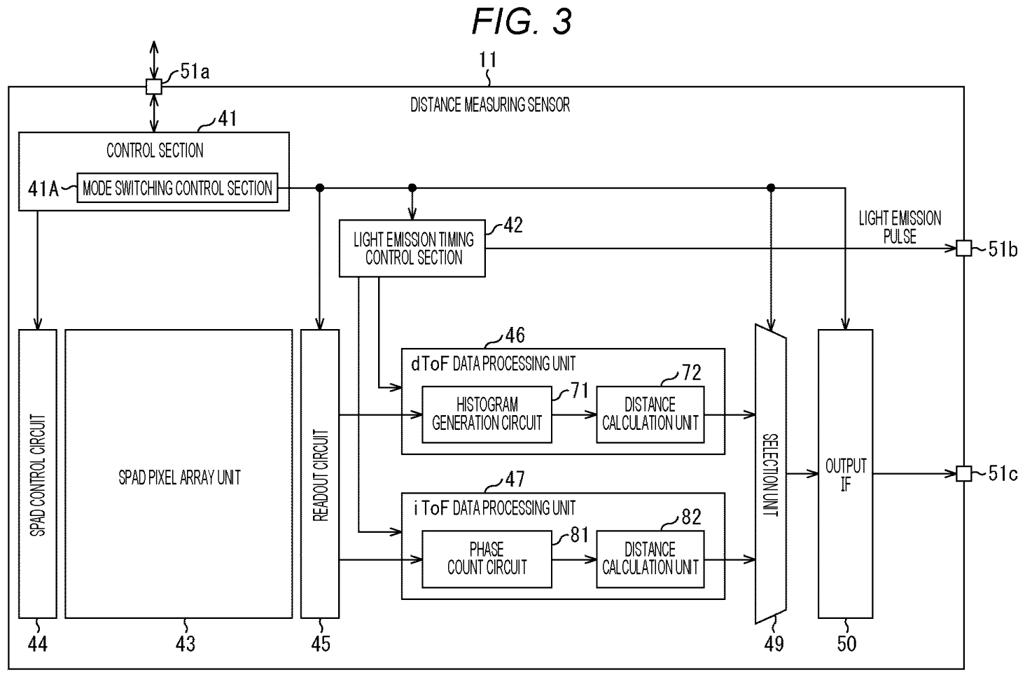

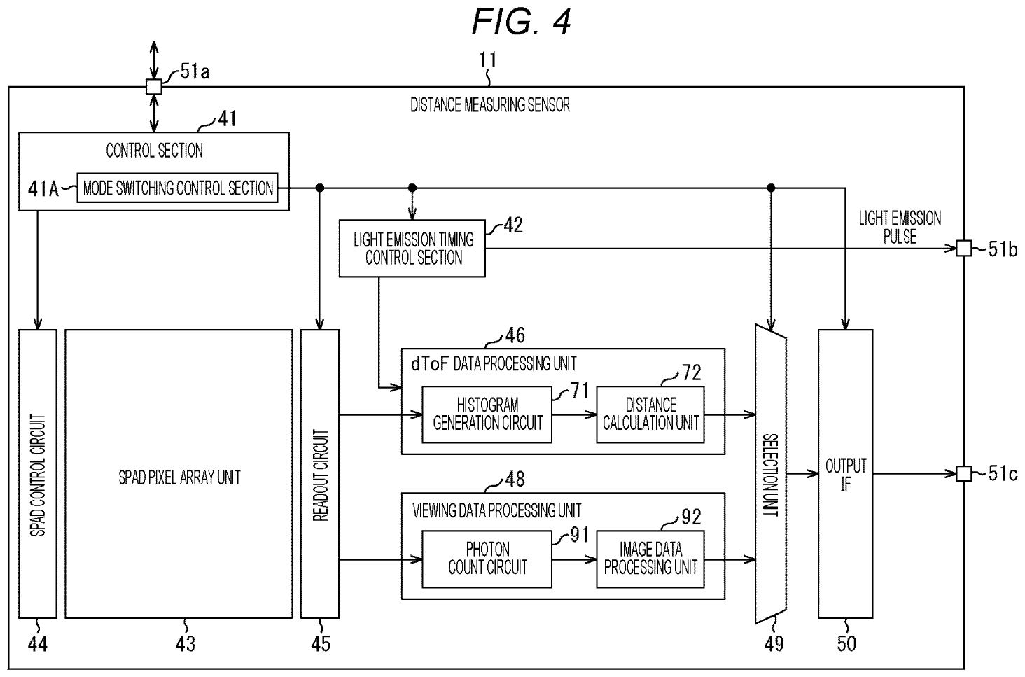

Note that, in the first embodiment, as illustrated in FIG. 2, the distance measuring sensor 11 includes the dToF data processing unit 46, the iToF data processing unit 47, and the viewing data processing unit 48, and is configured to appropriately switch the dToF distance measurement, the iToF distance measurement, and the viewing in a time division manner and output data according to the measurement mode, but it is also possible to employ the configuration illustrated in FIG. 3 or FIG. 4.

FIGS. 3 and 4 are block diagrams illustrating a modification of the distance measuring sensor 11 according to the first configuration example.

When the first modification illustrated in FIG. 3 is compared with FIG. 2, the viewing data processing unit 48 is omitted, and the distance measuring sensor 11 has a configuration corresponding to only two of the dToF distance measurement mode and the iToF distance measurement mode as the measurement modes.

On the other hand, comparing the second modification illustrated in FIG. 4 with FIG. 2, the iToF data processing unit 47 is omitted, and the distance measuring sensor 11 has a configuration corresponding to only two of the dToF distance measurement mode and the viewing mode as the measurement modes.

As illustrated in FIGS. 3 and 4, the distance measuring sensor 11 in the first configuration example of the first embodiment can be capable of only one of the iToF distance measurement or the viewing in addition to the dToF distance measurement.

### 3. Description of SPAD Pixel

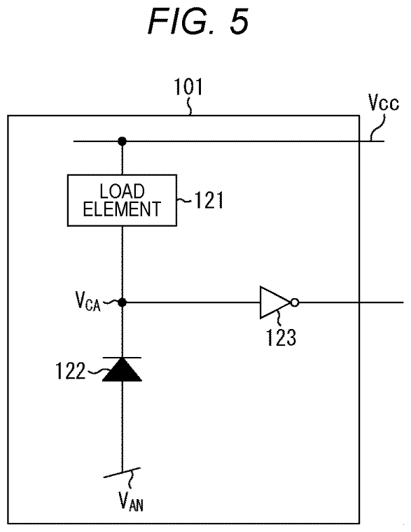

FIG. 5 illustrates a circuit configuration example that can be employed as the SPAD pixel of the SPAD pixel array unit 43.

The SPAD pixel 101 in FIG. 5 includes a load element (LOAD element) 121, a SPAD 122, and an inverter 123.

More specifically, one terminal of the load element 121 is connected to a power supply voltage Vcc, and the other terminal is connected to a cathode of the SPAD 122 and an input terminal of the inverter 123.

The other terminal of the load element 121 and an input terminal of the inverter 123 are connected to the cathode of the SPAD 122, and a predetermined power supply voltage V_{AN} is externally applied to an anode. The SPAD 122 is a photodiode (single photon avalanche photodiode) that performs avalanche amplification of generated electrons and outputs a signal of a cathode voltage V_{CA} when incident light is incident. The power supply voltage V_{AN} supplied to the anode of the SPAD 122 is, for example, a negative bias (negative potential) of about −20 V.

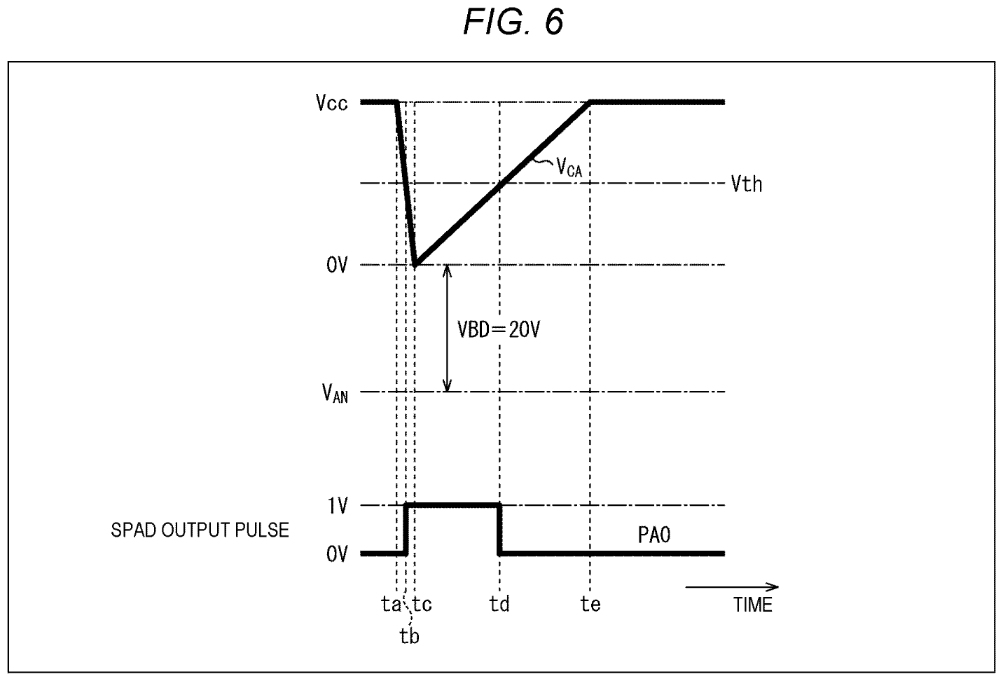

An operation of the SPAD pixel 101 of FIG. 5 will be described with reference to FIG. 6.

In order to detect photons with sufficient efficiency, a voltage (ExcessBias) larger than a breakdown voltage VBD of the SPAD 122 is applied to the SPAD 122. For example, assuming that the breakdown voltage VBD of the SPAD 122 is 20 V and a voltage larger than that by 3 V is applied, the power supply potential Vcc is 3 V.

Since the power supply voltage Vcc (for example, 3 V) is supplied to the cathode of the SPAD 122 and the power supply voltage V_{AN} (for example, −20 V) is supplied to the anode, a reverse voltage larger than the breakdown voltage VBD (=20 V) is applied to the SPAD 122, so that the SPAD 122 is set to the Geiger mode. In this state, the cathode voltage V_{CA} of the SPAD 122 is the same as the power supply voltage Vcc.

When photons are incident on the SPAD 122 at time ta, avalanche multiplication occurs, and a current flows through the SPAD 122. When the current flows through the SPAD 122, the current also flows through the load element 121, and a voltage drop occurs due to a resistance component of the load element 121.

When the cathode voltage V_{CA} of the SPAD 122 becomes lower than 0 V at time tc, the anode-cathode voltage of the SPAD 122 becomes lower than the breakdown voltage VBD, so that the avalanche amplification is stopped. Here, the current generated by the avalanche amplification flows through the load element 121 to generate a voltage drop, and the cathode voltage V_{CA} becomes lower than the breakdown voltage VBD along with the generated voltage drop to thereby stop the avalanche amplification, and this operation is a quenching operation.

When the avalanche amplification is stopped, the current flowing through the resistor of the load element 121 gradually decreases, and the cathode voltage V_{CA} returns to the original power supply voltage Vcc again at time te, thereby becoming capable of detecting a next new photon (recharge operation).

The inverter 123 outputs a High detection signal when the voltage drop occurs and the cathode voltage V_{CA} is lower than a predetermined threshold voltage Vth. Assuming that time tb is time when the cathode voltage V_{CA} becomes lower than the threshold voltage Vth due to the voltage drop, and time td is time when the cathode voltage V_{CA} becomes equal to or higher than the threshold voltage Vth due to the recharge operation, a High detection signal is output from the SPAD pixel 101 in a period from time tb to time td. The pulse output from the SPAD pixel 101 in response to the incidence of the photon is set as a SPAD output pulse PA0. The SPAD pixel 101 outputs the SPAD output pulse PA0 to the readout circuit 45 as a pixel signal.

The switching of whether the SPAD pixel 101 in FIG. 5 is an active pixel or an inactive pixel can be performed by connecting the cathode of the SPAD 122 and the input terminal of the inverter 123 to GND by a switching element that is not illustrated, and turning on or off the switching element on the basis of the active control signal. When the switching element is turned on, the cathode of the SPAD 122 becomes 0 V, and thus the anode-cathode voltage of the SPAD 122 becomes equal to or lower than the breakdown voltage VBD, thereby becoming a state in which no reaction occurs even when photons enter the SPAD 122.

The circuit configuration of the SPAD pixel is not limited to the circuit configuration illustrated in FIG. 5, and other configurations can be employed. For example, a configuration of an active recharge circuit that actively recovers a voltage drop caused by quenching may be employed.

### 4. Processing in Each Measurement Mode Using SPAD Pixel

Next, processing of each of the dToF data processing unit 46, the iToF data processing unit 47, and the viewing data processing unit 48 of the distance measuring sensor 11 will be described.

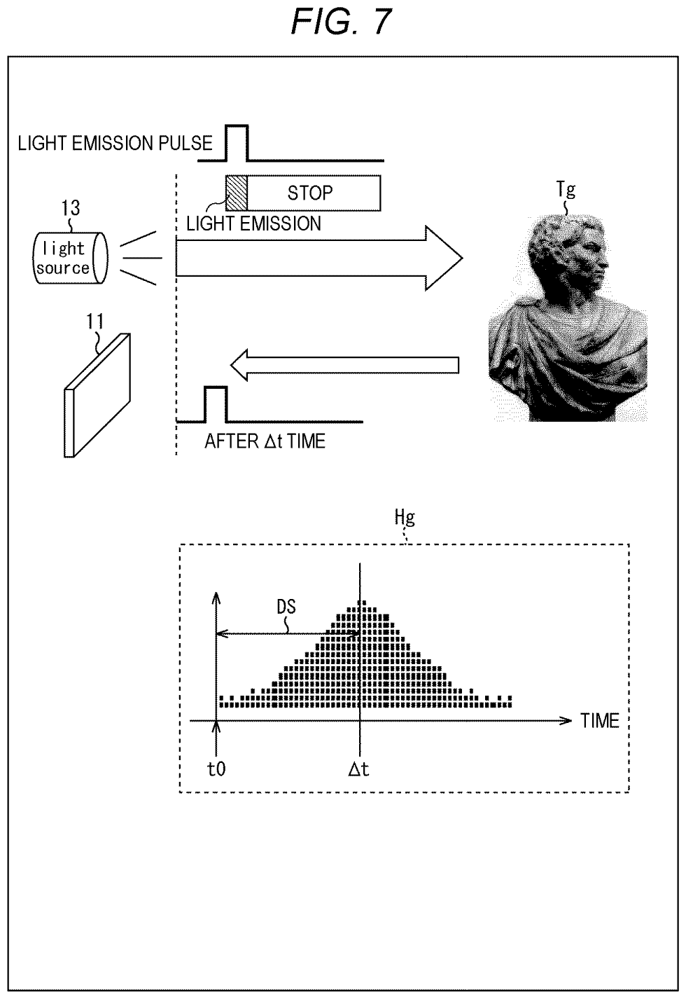

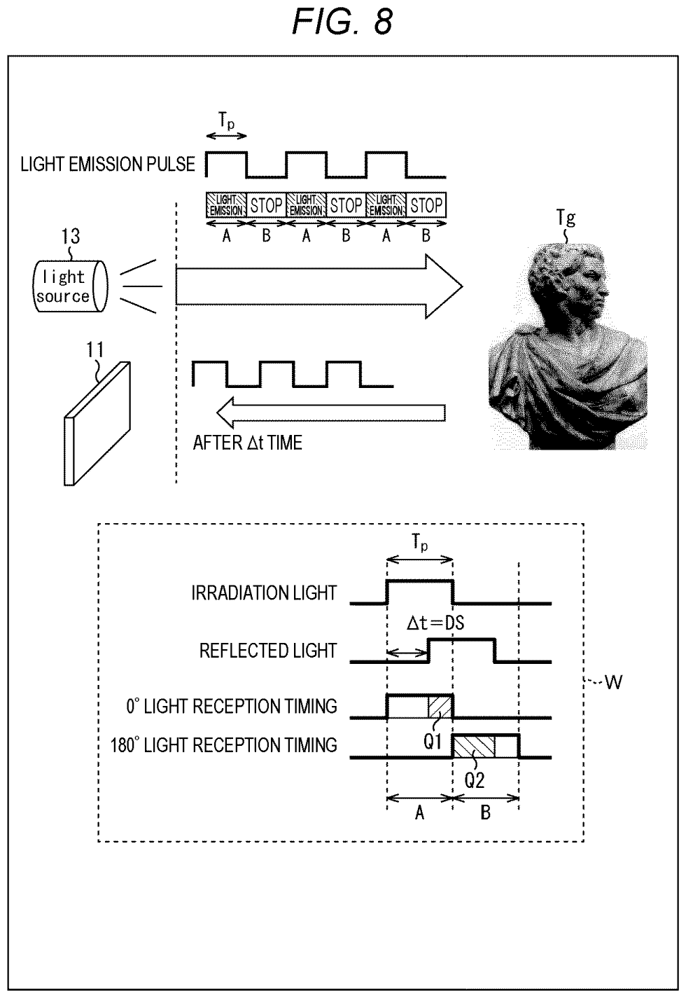

First, principles of dToF distance measurement and iToF distance measurement will be described with reference to FIGS. 7 and 8.

FIG. 7 is a diagram illustrating the principle of dToF distance measurement.

The light emitting unit 13 performs single light emission according to the light emission pulse illustrated in an upper part.

The irradiation light emitted from the light emitting unit 13 is reflected by an object Tg and is incident on the distance measuring sensor 11 as reflected light after Δt time. However, actually, light such as external light or reflected light that is secondarily reflected is incident at other than after Δt time according to a distance DS to the object Tg. Accordingly, by repeating emission and reception of the irradiation light multiple times (for example, several to several hundred times), a histogram Hg as illustrated in a lower part of FIG. 7 is generated. Then, an arrival time Δt of the irradiation light is determined on the basis of the peak value of the histogram Hg, and the distance DS to the object Tg is calculated from the determined arrival time Δt.

FIG. 8 is a diagram illustrating the principle of iToF distance measurement.

The light emitting unit 13 periodically repeats light emission and extinction (stop of light emission) in accordance with the light emission pulse illustrated in the upper part. Here, a light emission period A and a stop period B of the irradiation light are the same period Tp.

The irradiation light emitted from the light emitting unit 13 is reflected by the object Tg and is incident on the distance measuring sensor 11 as reflected light after Δt time. That is, a delay time Δt of the reflected light incident on the distance measuring sensor 11 corresponds to the distance DS to the object.

Here, as illustrated in a lower part frame W of FIG. 8, when the light reception timing of the distance measuring sensor 11 is divided into a 0° light reception timing having the same phase as the light emission timing of the irradiation light and a 180° timing having a phase obtained by inverting the light emission timing of the irradiation light, a ratio between a charge Q1 received at the 0° light reception timing and a charge Q2 received at the 180° timing changes with the delay time Δt according to the distance DS. Therefore, the distance DS to the object Tg can be obtained from the ratio of the charge Q1 in the light receiving period with the phase of 0° to the charge Q2 in the light receiving period with the phase of 180°.

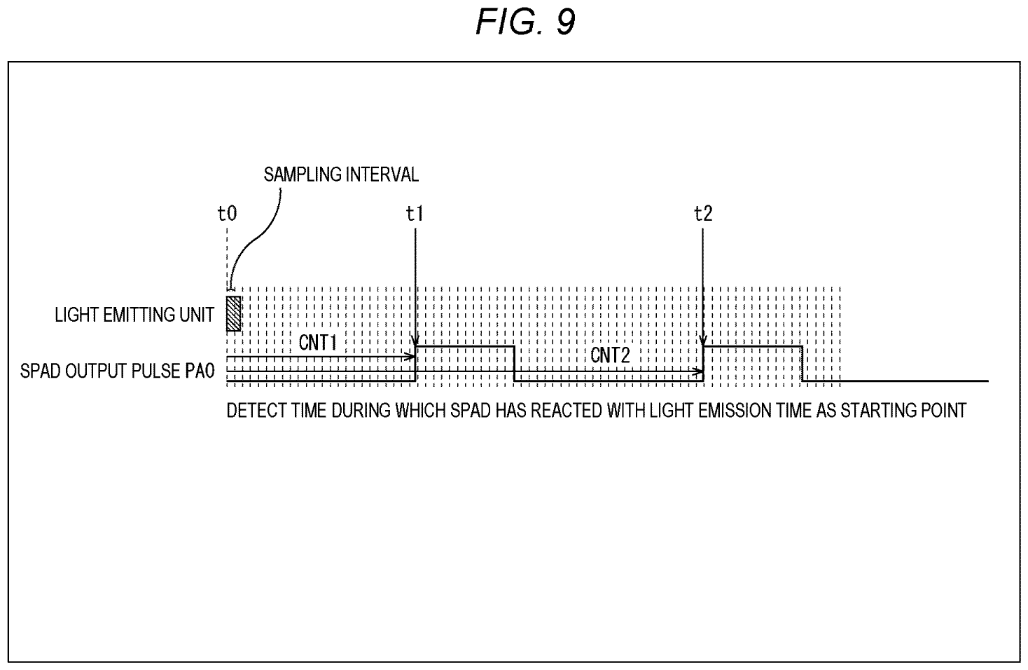

FIG. 9 is a diagram illustrating processing of the dToF data processing unit 46.

The histogram generation circuit 71 detects the light emission timing of the irradiation light in the light emitting unit 13 on the basis of the light emission pulse from the light emission timing control section 42, and starts counting.

Then, the histogram generation circuit 71 acquires the time when the SPAD 122 has reacted, that is, the time during which the SPAD output pulse PA0 supplied from the readout circuit 45 becomes High for each pixel, and creates a histogram. Here, the sampling interval for sampling (detecting) whether the SPAD output pulse PA0 is High or Low is, for example, an interval of the order of gigahertz (GHz).

Note that the SPAD output pulse PA0 may become High multiple times for one light emission due to factors such as external light, secondary reflected light, and noise. In the example of FIG. 9, the SPAD 122 has reacted twice at time t1 and time t2 after time t0 at which light emission is started. For example, the count value from time t0 to time t1 is CNT1, and the count value from time t0 to time t2 is CNT2.

The histogram generation circuit 71 repeatedly executes emission of the irradiation light and reception of the reflected light a predetermined number of times (for example, several to several hundred times), generates a histogram of the count value for each pixel, and supplies the generated histogram data to the distance calculation unit 72.

The distance calculation unit 72 detects a peak value of the histogram for the histogram data supplied from the histogram generation circuit 71, calculates a distance corresponding to the flight time of the peak value, and outputs the distance to the selection unit 49.

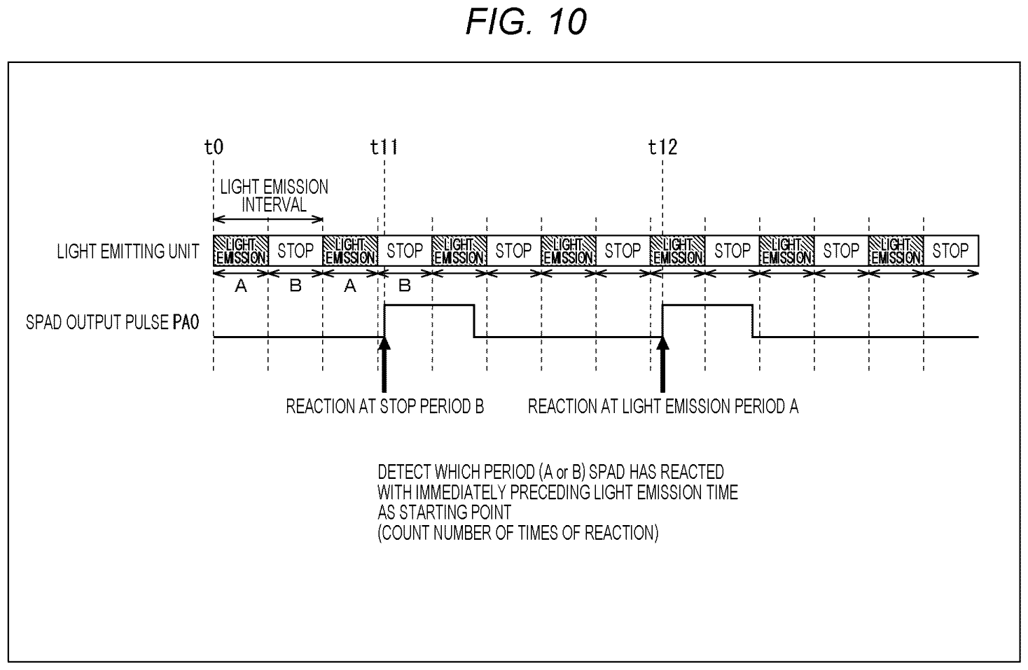

FIG. 10 is a diagram illustrating processing of the iToF data processing unit 47.

On the basis of the light emission pulse from the light emission timing control section 42, the phase counting circuit 81 identifies a light emission period A having the same phase (phase 0 degrees) as the light emission timing of the irradiation light and a stop period B having a phase (phase 180 degrees) obtained by inverting the light emission timing of the irradiation light. Here, the light emission interval of the irradiation light is an interval of several tens to several hundreds of megahertz (MHz) order.

The phase counting circuit 81 detects, for each pixel, whether the timing at which the SPAD 122 has reacted, in other words, the timing at which the SPAD output pulse PA0 supplied from the readout circuit 45 has changed to High is the light emission period A or the stop period B. In the example of FIG. 10, after time t0 at which light emission is started, the SPAD 122 has reacted twice at time t11 and time t12. For example, the reaction of the SPAD 122 at time t11 is a reaction in the stop period B, and the reaction of the SPAD 122 at time t12 is a reaction in the light emission period A.

The phase counting circuit 81 counts each of the number of times of reaction in the light emission period A and the number of times of reaction in the stop period B, and supplies the counted numbers to the distance calculation unit 82.

The distance calculation unit 82 calculates the distance to the subject for each pixel on the basis of the ratio between the number of times of reaction in the light emission period A and the number of times of reaction in the stop period B, and outputs the distance to the selection unit 49.

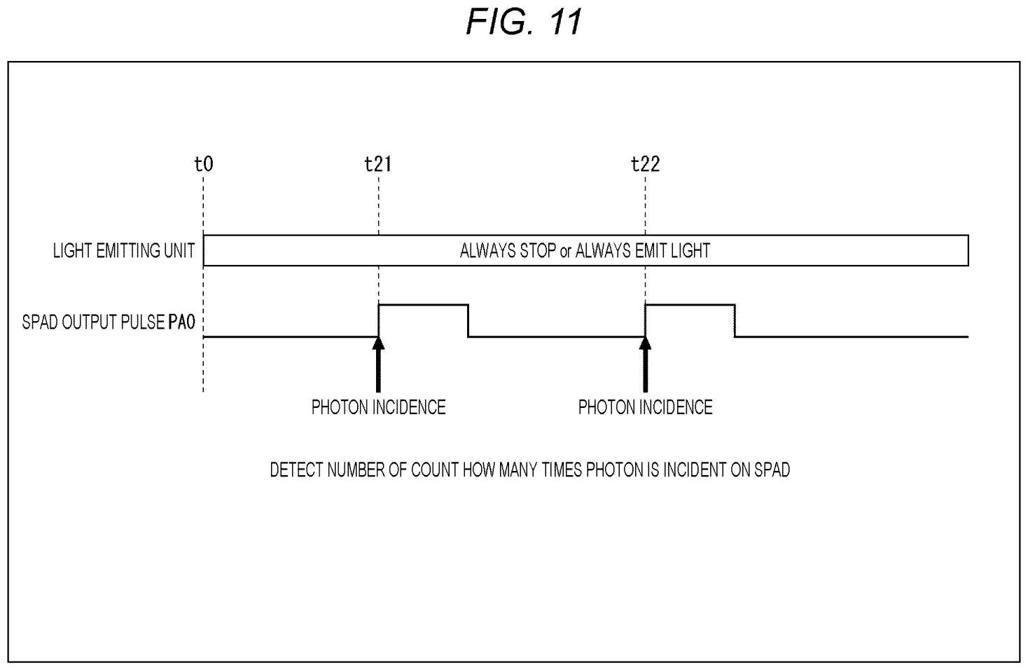

FIG. 11 is a diagram illustrating processing of the viewing data processing unit 48.

In the viewing measurement mode, the light emitting unit 13 always stops light emission or always emits light. In the present embodiment, light emission is always stopped.

The photon counting circuit 91 counts the number of times of reaction of the SPAD 122 within a predetermined measurement period, that is, the number of times of incidence of photons for each pixel, and supplies a counting result to the image data processing unit 92. In the example of FIG. 11, after time t0 at which light emission is started, the SPAD 122 has reacted twice at time t21 and time t22.

The image data processing unit 92 generates image data in which the counting result of photons measured in each pixel is set to a pixel value (luminance value) according to the received light amount, and supplies the image data to the selection unit 49.

### 5. Operation of Light Emission Timing Control Section

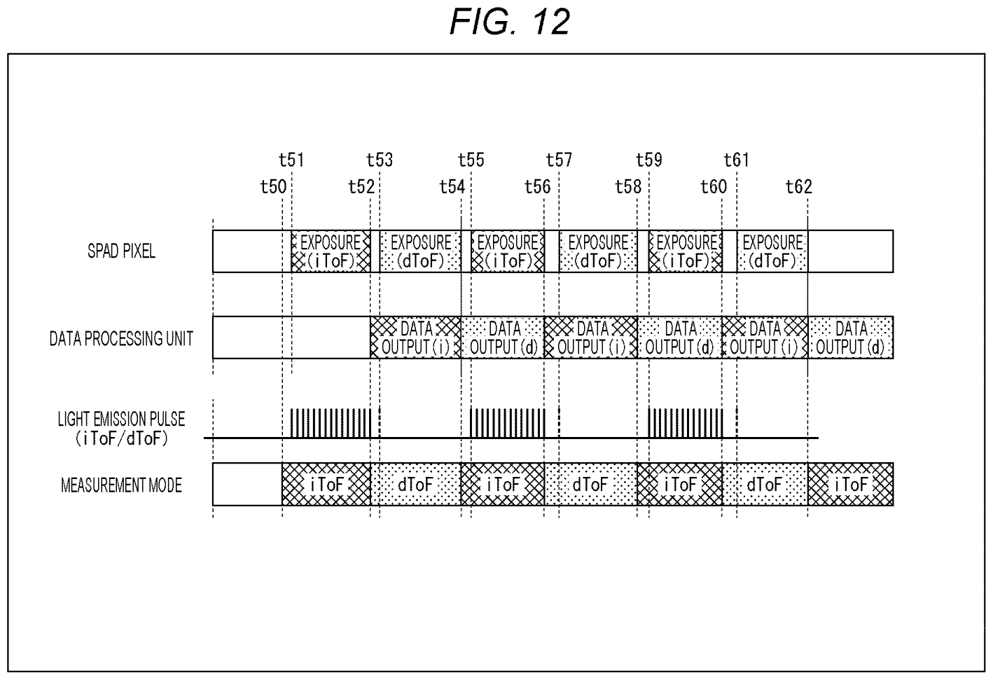

The operation of the light emission timing control section 42 will be described with reference to the timing chart of FIG. 12.

Since the light emitting unit 13 always stops light emission when the measurement mode is the viewing mode, a case where the measurement mode is switched between the dToF distance measurement mode and the iToF distance measurement mode will be described in the example of FIG. 12.

The iToF distance measurement and the dToF distance measurement are executed at different timings by time division processing in order to prevent interference.

At time t50, the mode switching control section 41A switches the measurement mode to the iToF distance measurement mode. That is, the mode switching control section 41A supplies the iToF distance measurement mode to the light emission timing control section 42 as the measurement mode to be executed. Thus, the light emission timing control section 42 performs light emission control in the iToF distance measurement mode from time t50 to time t52.

Furthermore, from time t51 to time t52, the light emission timing control section 42 generates a light emission pulse having a modulation frequency of several tens to several hundreds of MHz, outputs the light emission pulse to the LD 12 via the input-output terminal 51b, and also supplies the light emission pulse to the iToF data processing unit 47. Each SPAD pixel 101 of the SPAD pixel array unit 43 outputs a High SPAD output pulse PA0 to the iToF data processing unit 47 via the readout circuit 45 in response to incidence of photons.

Next, at time t52, the mode switching control section 41A switches the measurement mode to the dToF distance measurement mode. That is, the mode switching control section 41A supplies the dToF distance measurement mode to the light emission timing control section 42 as the measurement mode to be executed. Thus, the light emission timing control section 42 performs light emission control in the dToF distance measurement mode from time t52 to time t54. Furthermore, from time t52 to time t54, the iToF data processing unit 47 calculates and outputs the distance to the subject for each pixel on the basis of the ratio between the number of times of reaction in the light emission period A and the number of times of reaction in the stop period B during the period from time t51 to time t52.

Furthermore, from time t53 to time t54, the light emission timing control section 42 generates a light emission pulse that is High for a predetermined period, outputs the light emission pulse to the LD 12 via the input-output terminal 51b, and also supplies the light emission pulse to the dToF data processing unit 46. Each SPAD pixel 101 of the SPAD pixel array unit 43 outputs a High SPAD output pulse PA0 to the dToF data processing unit 46 via the readout circuit 45 in response to incidence of photons. During the period from time t53 to time t54, the light emission pulse becomes High multiple times (for example, several to several hundred times).

Next, at time t54, the mode switching control section 41A switches the measurement mode to the iToF distance measurement mode. That is, the mode switching control section 41A supplies the iToF distance measurement mode to the light emission timing control section 42 as the measurement mode to be executed. Thus, the light emission timing control section 42 performs light emission control in the iToF distance measurement mode from time t54 to time t56. Furthermore, from time t54 to time t56, the dToF data processing unit 46 calculates and outputs the distance to the subject for each pixel on the basis of the histogram of the time when the SPAD 122 has reacted generated during the period from time t53 to time t54.

Furthermore, from time t55 to time t56, the light emission timing control section 42 generates a light emission pulse having a modulation frequency of several tens to several hundreds of MHz, outputs the light emission pulse to the LD 12 via the input-output terminal 51b, and also supplies the light emission pulse to the iToF data processing unit 47. Each SPAD pixel 101 of the SPAD pixel array unit 43 outputs the High SPAD output pulse PA0 to the iToF data processing unit 47 via the readout circuit 45 in response to incidence of photons.

Next, at time t56, the mode switching control section 41A switches the measurement mode to the dToF distance measurement mode. That is, the mode switching control section 41A supplies the dToF distance measurement mode to the light emission timing control section 42 as the measurement mode to be executed. Thus, the light emission timing control section 42 performs light emission control in the dToF distance measurement mode from time t56 to time t58. Furthermore, from time t56 to time t58, the iToF data processing unit 47 calculates and outputs the distance to the subject for each pixel on the basis of the ratio between the number of times of reaction in the light emission period A and the number of times of reaction in the stop period B during the period from time t55 to time t56.

Furthermore, from time t57 to time t58, the light emission timing control section 42 generates a light emission pulse that is High for a predetermined period, outputs the light emission pulse to the LD 12 via the input-output terminal 51b, and also supplies the light emission pulse to the dToF data processing unit 46. Each SPAD pixel 101 of the SPAD pixel array unit 43 outputs the High SPAD output pulse PA0 to the dToF data processing unit 46 via the readout circuit 45 in response to incidence of photons. During a period from time t57 to time t58, the light emission pulse becomes High multiple times (for example, several to several hundred times).

Next, at time t58, the mode switching control section 41A switches the measurement mode to the iToF distance measurement mode. That is, the mode switching control section 41A supplies the iToF distance measurement mode to the light emission timing control section 42 as the measurement mode to be executed. Thus, the light emission timing control section 42 performs light emission control in the iToF distance measurement mode from time t58 to time t60. Furthermore, from time t58 to time t60, the dToF data processing unit 46 calculates and outputs the distance to the subject for each pixel on the basis of the histogram of the time when the SPAD 122 has reacted generated during the period from time t57 to time t58.

Furthermore, from time t59 to time t60, the light emission timing control section 42 generates a light emission pulse having a modulation frequency of several tens to several hundreds of MHz, outputs the light emission pulse to the LD 12 via the input-output terminal 51b, and also supplies the light emission pulse to the iToF data processing unit 47. Each SPAD pixel 101 of the SPAD pixel array unit 43 outputs the High SPAD output pulse PA0 to the iToF data processing unit 47 via the readout circuit 45 in response to incidence of photons.

The same applies to the operation after time t60.

As described above, the distance measuring sensor 11 switches the measurement mode between the iToF distance measurement mode and the dToF distance measurement mode in a time division manner. More specifically, in a period in which exposure (light reception) in one measurement mode is executed, the distance measuring sensor 11 executes data processing in the other measurement mode and outputs distance measurement data. Furthermore, data processing in one measurement mode is executed and distance measurement data is output in a period during which exposure (light reception) in the other measurement mode is executed. Thus, measurement in a plurality of measurement modes can be efficiently performed.

### 6. Second Configuration Example of First Embodiment of Distance Measuring Sensor

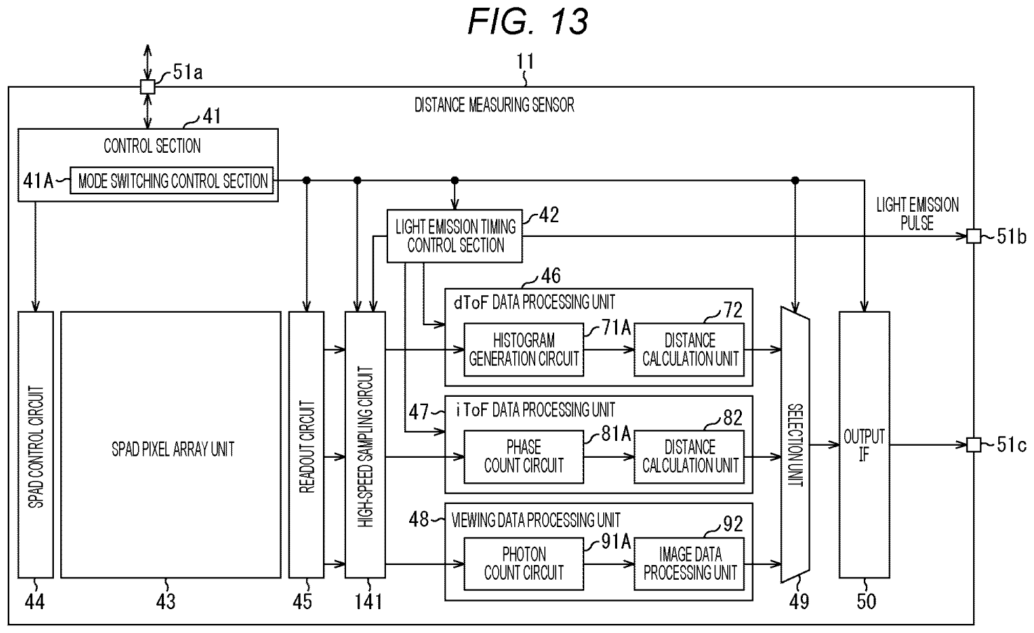

FIG. 13 is a block diagram illustrating a second configuration example of the first embodiment of the distance measuring sensor 11.

In FIG. 13, parts corresponding to those in the first configuration example illustrated in FIG. 2 are denoted by the same reference numerals, and description of the parts will be omitted as appropriate, and different parts will be described.

In the second configuration example illustrated in FIG. 13, as compared with the first configuration example illustrated in FIG. 2, a high-speed sampling circuit 141 is newly added at a subsequent stage of the readout circuit 45.

Furthermore, with the addition of the high-speed sampling circuit 141, the histogram generation circuit 71 of the dToF data processing unit 46, the phase counting circuit 81 of the iToF data processing unit 47, and the photon counting circuit 91 of the viewing data processing unit 48 in the first configuration example are changed to a histogram generation circuit 71A, a phase counting circuit 81A, and a photon counting circuit 91A, respectively.

The distance measuring sensor 11 according to the second configuration example commonly uses the high-speed sampling circuit 141 in each measurement mode of the iToF distance measurement mode, the dToF distance measurement mode, and the viewing mode.

The high-speed sampling circuit 141 samples (the state of) the SPAD output pulse PA0 of each SPAD pixel 101 supplied from the readout circuit 45 in each measurement mode at a first frequency (high frequency), and outputs the n-bit (n>1) sampling result to the subsequent stage at a second frequency (low frequency) lower than the first frequency. Here, a sampling interval at the time of sampling at a high frequency is a high-speed sampling interval SD1, and a time interval at which an n-bit sampling result is output is a low-speed output interval SD2.

The histogram generation circuit 71A generates histogram data by using the high-speed sampling result supplied from the high-speed sampling circuit 141, and supplies the histogram data to the distance calculation unit 72.

The phase counting circuit 81A counts the number of times of reception of the reflected light in each of the light emission period A (phase 0 degrees) and the stop period B (phase 180 degrees) using the high-speed sampling result supplied from the high-speed sampling circuit 141.

The photon counting circuit 91A calculates a photon counting result by using the high-speed sampling result supplied from the high-speed sampling circuit 141, and supplies the photon counting result to the image data processing unit 92.

### 7. Operation of High-Speed Sampling Circuit

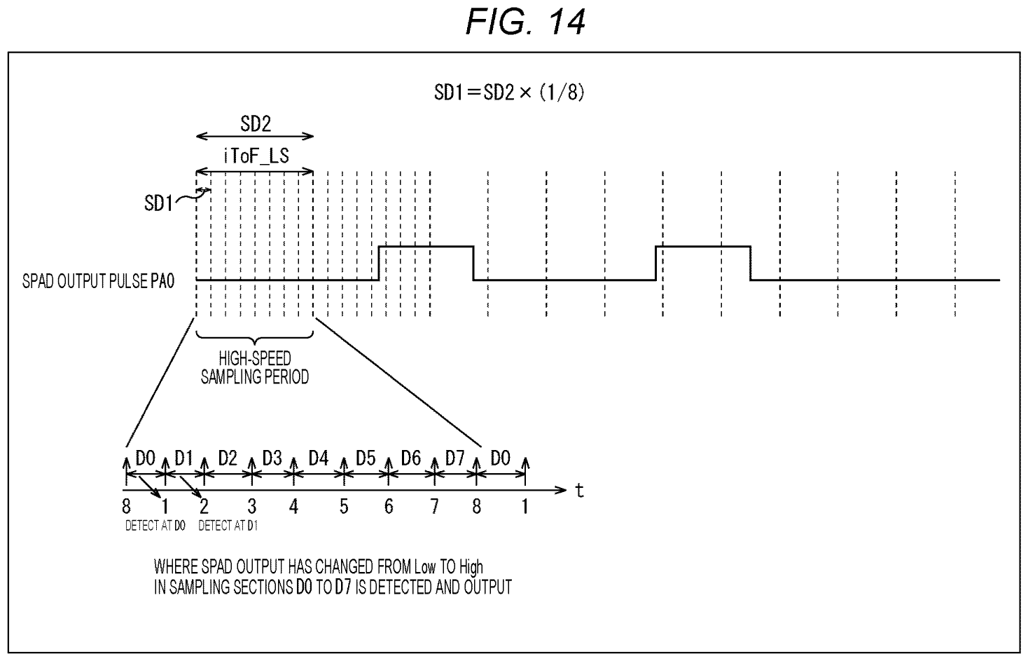

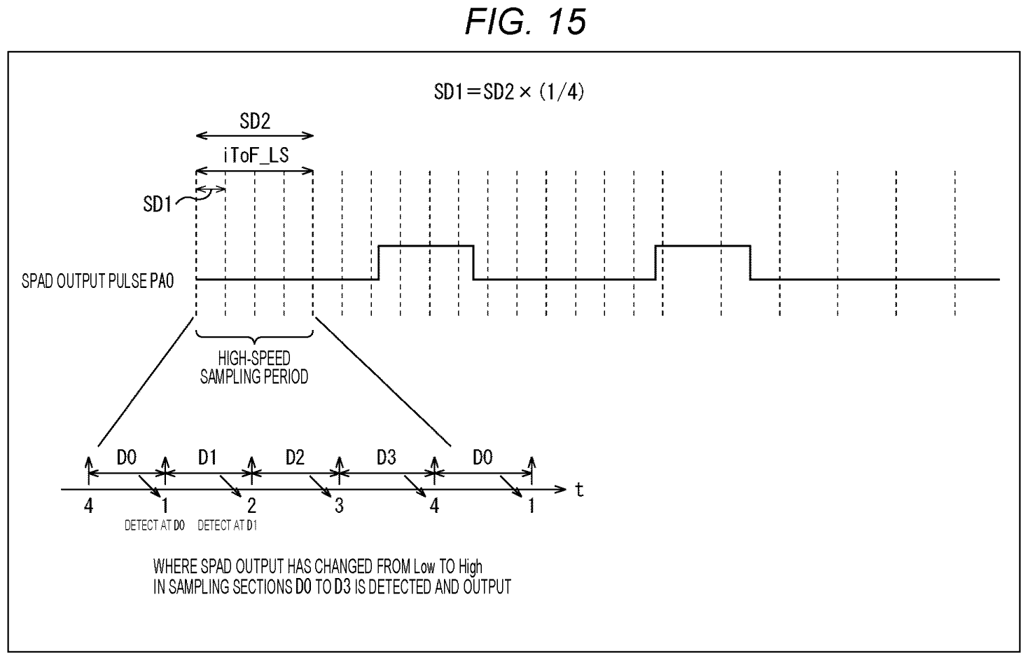

The operation of the high-speed sampling circuit 141 will be described with reference to FIGS. 14 and 15.

FIG. 14 is a diagram illustrating an operation example of the high-speed sampling circuit 141.

The high-speed sampling circuit 141 executes processing of sampling (the state of) the SPAD output pulse PA0 at a high frequency in a predetermined high-speed sampling period, and outputs the sampling result as a set of n-bit data in units of high-speed sampling period. Here, the sampling interval at the time of sampling at a high frequency is the high-speed sampling interval SD1, and the time interval at which the n-bit sampling result is output is the low-speed output interval SD2.

FIG. 14 illustrates an example in which n=8, that is, the sampling result obtained by performing the high-speed sampling eight times is output as 8-bit data at a low frequency of ⅛ of the high-speed sampling. SD1=SD2×(⅛), and the high-speed sampling period is equal to the low-speed output interval SD2.

In the example of FIG. 14, the high-speed sampling circuit 141 divides the high-speed sampling period (low-speed output interval SD2) into eight sections D0 to D7, and outputs the first bit as “High” in a case where the SPAD 122 has reacted in the section DO, the second bit as “High” in a case where the SPAD 122 has reacted in the section D1, and the third bit as “High” in a case where the SPAD 122 has reacted in the section D2. Similarly, in a case where the SPAD 122 has reacted in the sections D3 to D7, the fourth bit to the eighth bit are set to “High” and output.

Also in the iToF distance measurement, in order to commonly use the high-speed sampling circuit 141, the light emission interval iToF_LS of the irradiation light in the iToF distance measurement needs to be a multiple of the high-speed sampling interval SD1. Furthermore, the high-speed sampling period (low-speed output interval SD2) needs to be the same as the light emission interval iToF_LS of the irradiation light in the iToF distance measurement or a multiple of the light emission interval iToF_LS.

In the example of FIG. 14, the light emission interval iToF_LS of the irradiation light in the iToF distance measurement is eight times the high-speed sampling interval SD1, and the high-speed sampling period (low-speed output interval SD2) is the same as the light emission interval iToF_LS of the irradiation light in the iToF distance measurement.

FIG. 15 illustrates an example in which n=4, that is, the sampling result obtained by performing the high-speed sampling four times is output as 4-bit data at a low frequency of ¼ of the high-speed sampling. SD1=SD2×(¼), and the high-speed sampling period is equal to the low-speed output interval SD2.

In the example of FIG. 15, the high-speed sampling circuit 141 divides the high-speed sampling period (low-speed output interval SD2) into four sections D0 to D3, and outputs the first bit as “High” in a case where the SPAD 122 has reacted in the section D0, the second bit as “High” in a case where the SPAD 122 has reacted in the section D1, the third bit as “High” in a case where the SPAD 122 has reacted in the section D2, and the fourth bit as “High” in a case where the SPAD 122 has reacted in the section D3.

The light emission interval iToF_LS of the irradiation light in the iToF distance measurement needs to be a multiple of the high-speed sampling interval SD1. Furthermore, the high-speed sampling period (low-speed output interval SD2) needs to be the same as the light emission interval iToF_LS of the irradiation light in the iToF distance measurement or a multiple of the light emission interval iToF_LS.

In the example of FIG. 15, the light emission interval iToF_LS of the irradiation light in the iToF distance measurement is four times the high-speed sampling interval SD1, and the high-speed sampling period (low-speed output interval SD2) is the same as the light emission interval iToF_LS of the irradiation light in the iToF distance measurement.

### 8. First Configuration Example of High-Speed Sampling Circuit

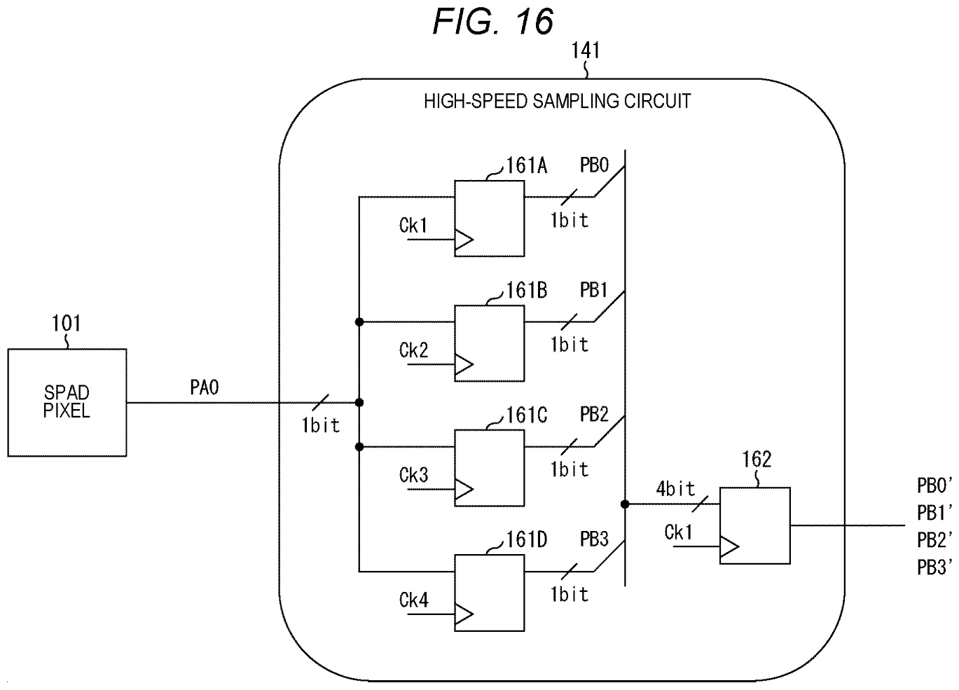

FIG. 16 illustrates a first configuration example of the high-speed sampling circuit 141.

The high-speed sampling circuit 141 of FIG. 16 illustrates a configuration example in a case of outputting a 4-bit sampling result at a low frequency of ¼ of high-speed sampling, which is the example illustrated in FIG. 15.

The high-speed sampling circuit 141 includes four 1-bit latch circuits 161A to 161D and one 4-bit latch circuit 162.

The SPAD output pulse PA0 from the SPAD pixel 101 is input to the four 1-bit latch circuits 161A to 161D. In order to ensure a timing relationship of high-speed operation, the length of wiring between the SPAD pixel 101 and each of the 1-bit latch circuits 161A to 161D is set equal.

The 1-bit latch circuit 161 outputs the latch output pulse PB obtained by latching the SPAD output pulse PA0 to the 4-bit latch circuit 162 on the basis of an input clock Ck. Here, the clock Ck input to the 1-bit latch circuit 161A is referred to as a clock Ck1, and the latch output pulse PB output to the 4-bit latch circuit 162 is referred to as a latch output pulse PB0. The clock Ck input to the 1-bit latch circuit 161B is referred to as a clock Ck2, and the latch output pulse PB output to the 4-bit latch circuit 162 is referred to as a latch output pulse PB1. The clock Ck input to the 1-bit latch circuit 161C is referred to as a clock Ck3, and the latch output pulse PB output to the 4-bit latch circuit 162 is referred to as a latch output pulse PB2. The clock Ck input to the 1-bit latch circuit 161D is referred to as a clock Ck4, and the latch output pulse PB output to the 4-bit latch circuit 162 is referred to as a latch output pulse PB3.

The frequencies of the clocks Ck1 to Ck4 input to the 1-bit latch circuits 161A to 161D are low frequencies that are ¼ of the high frequencies corresponding to the high-speed sampling interval SD1. Furthermore, the clocks Ck1 to Ck4 are signals whose phases are shifted from the clock Ck of the adjacent 1-bit latch circuit 161 by the high-speed sampling interval SD1.

The 4-bit latch circuit 162 latches the latch output pulses PB0 to PB3 output from the 1-bit latch circuits 161A to 161D, respectively, on the basis of the input clock Ck1, and outputs the result to the subsequent stage as a 4-bit latch output pulse [PB0′, PB1′, PB2′, and PB3′].

The processing timing of the 4-bit latch circuit 162 is delayed by one cycle by the clock Ck1 from the processing of the 1-bit latch circuits 161A to 161D.

### 9. High-Speed Sampling Processing in dToF Distance Measurement Mode

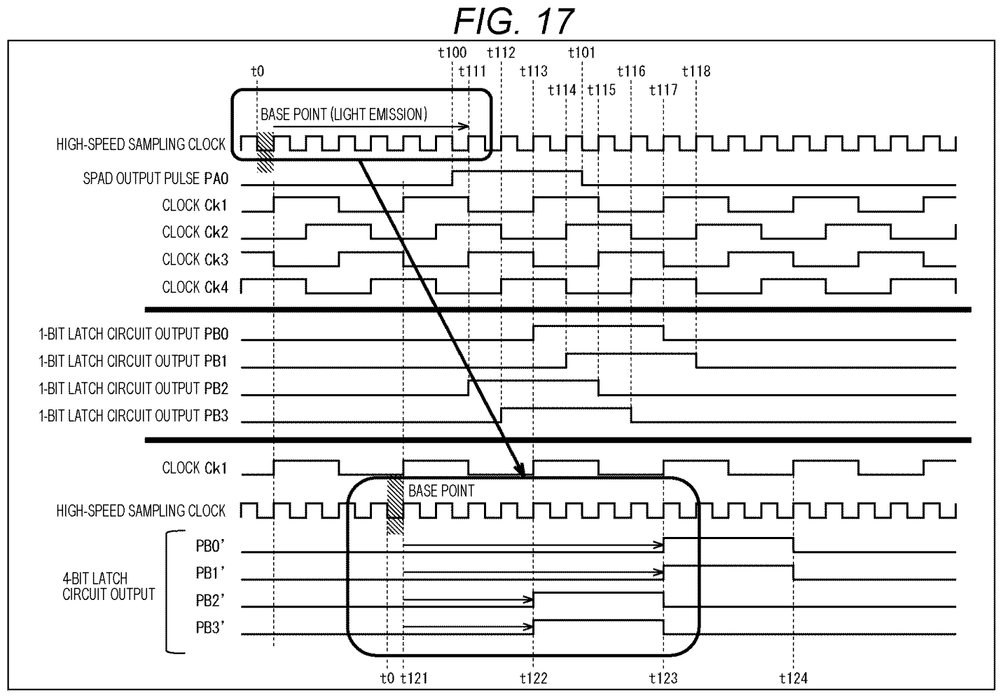

FIG. 17 is a time chart illustrating the processing of the high-speed sampling circuit 141 of FIG. 16 in a case where the measurement mode is the dToF distance measurement mode.

In the example of FIG. 17, the sampling clock (high-speed sampling clock) of a high frequency corresponding to the high-speed sampling interval SD1 is 1 GHz. In this case, the low-frequency clocks Ck1 to Ck4 corresponding to the low-speed output interval SD2 are 250 MHz.

A time at which the light emitting unit 13 emits irradiation light, which is a base point of light emission, is defined as time t0.

It is assumed that the SPAD pixel 101 receives the reflected light of the irradiation light emitted from the light emitting unit 13 at time t0 and outputs the High SPAD output pulse PA0 in a period from time t100 to time t101. In this case, assuming that the SPAD output pulse PA0 is sampled by a high-speed sampling clock of 1 GHz, the High SPAD output pulse PA0 is detected for the first time at a rise at time till after time t100, and thus the High SPAD output pulse PA0 is detected at the seventh cycle.

At time till after time t100, the clock Ck3 input to the 1-bit latch circuit 161C becomes High, and the 1-bit latch circuit 161C detects the High SPAD output pulse PA0 and changes the latch output pulse PB2 to High. Then, at time t115 when the clock Ck3 becomes High next, the 1-bit latch circuit 161C detects the Low SPAD output pulse PA0 and changes the latch output pulse PB2 to Low. Therefore, the latch output pulse PB2 becomes High during the period from time till to time t115.

At time t112 after time till, the clock Ck4 input to the 1-bit latch circuit 161D becomes High, and the 1-bit latch circuit 161D detects the High SPAD output pulse PA0 and changes the latch output pulse PB3 to High. Then, at time t116 when the clock Ck4 becomes High next, the 1-bit latch circuit 161D detects the Low SPAD output pulse PA0 and changes the latch output pulse PB3 to Low. Therefore, the latch output pulse PB2 becomes High during the period from time t112 to time t116.

At time t113 after time t112, the clock Ck1 input to the 1-bit latch circuit 161A becomes High, and the 1-bit latch circuit 161A detects the High SPAD output pulse PA0 and changes the latch output pulse PB0 to High. Then, at time t117 when the clock Ck1 becomes High next, the 1-bit latch circuit 161A detects the Low SPAD output pulse PA0 and changes the latch output pulse PB0 to Low. Therefore, the latch output pulse PB0 becomes High during the period from time t113 to time t117.

At time t114 after time t113, the clock Ck2 input to the 1-bit latch circuit 161B becomes High, and the 1-bit latch circuit 161B detects the High SPAD output pulse PA0 and changes the latch output pulse PB1 to High. Then, at time t118 when the clock Ck2 becomes High next, the 1-bit latch circuit 161B detects the Low SPAD output pulse PA0 and changes the latch output pulse PB1 to Low. Therefore, the latch output pulse PB1 becomes High during the period from time t114 to time t118.

The 4-bit latch circuit 162 detects the latch output pulses PB0 to PB3 output from the 1-bit latch circuits 161A to 161D, respectively, on the basis of the input clock Ck1.

Since the processing timing of the 4-bit latch circuit 162 is delayed by one cycle by the clock Ck1 from the time of processing of the 1-bit latch circuits 161A to 161D, the base point (time t0) of light emission in a lower part of FIG. 17 is shifted by one cycle by the clock Ck1 from the base point of light emission in the upper part.

After the base point of light emission in the 4-bit latch circuit 162 (time t0), at time t121 when the clock Ck1 first becomes High, the 4-bit latch circuit 162 detects the latch output pulses PB0 to PB3 and outputs the 4-bit latch output pulse [PB0′, PB1′, PB2′, and PB3′]. At time t121, since all the latch output pulses PB0 to PB3 are Low, the 4-bit latch circuit 162 outputs the 4-bit latch output pulse [PB0′, PB1′, PB2′, and PB3′]=[Low, Low, Low, and Low].

Next, at time t122 when the clock Ck1 becomes High, the 4-bit latch circuit 162 detects the latch output pulses PB0 to PB3 and outputs the 4-bit latch output pulse [PB0′, PB1′, PB2′, and PB3′]. At time t122, since the latch output pulses PB0 and PB1 are Low and the latch output pulses PB2 and PB3 are High, the 4-bit latch circuit 162 outputs the 4-bit latch output pulse [PB0′, PB1′, PB2′, and PB3′]=[Low, Low, High, and High].

Next, at time t123 when the clock Ck1 becomes High, the 4-bit latch circuit 162 detects the latch output pulses PB0 to PB3 and outputs the 4-bit latch output pulse [PB0′, PB1′, PB2′, and PB3′]. At time t123, since the latch output pulses PB0 and PB1 are High and the latch output pulses PB2 and PB3 are Low, the 4-bit latch circuit 162 outputs the 4-bit latch output pulse [PB0′, PB1′, PB2′, and PB3′]=[High, High, Low, and Low].

As described above, the high-speed sampling circuit 141 outputs the 4-bit latch output pulse [PB0′, PB1′, PB2′, and PB3′] with the low sampling clock of 250 MHz. After the base point of light emission (time t0), the 4-bit latch output pulse [PB0′, PB1′, PB2′, and PB3′] becomes [Low, Low, Low, and Low], [Low, Low, High, and High], and [High, High, Low, and Low], and thus becomes High in the seventh cycle, similarly to the case of sampling the SPAD output pulse PA0 with the high-speed sampling clock of 1 GHz. As described above, the high-speed sampling circuit 141 converts information of 4 cycles of 1 GHz into information of 4 bits of 250 MHz and outputs the information. By converting high-speed time information into low-speed information of a plurality of bits and outputting the information, timing processing can be easily performed in the subsequent circuit.

### 10. dToF Data Processing of dToF Data Processing Unit

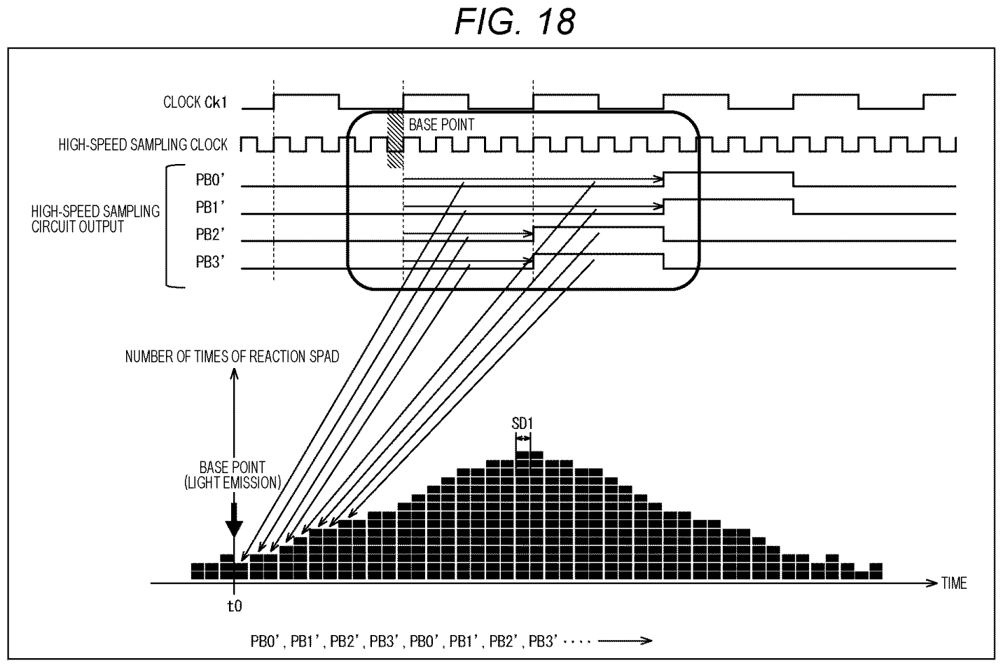

FIG. 18 illustrates processing of the histogram generation circuit 71A based on the 4-bit latch output pulse sequentially output from the high-speed sampling circuit 141.

As described with reference to FIG. 17, the 4-bit latch output pulse [PB0′, PB1′, PB2′, and PB3′] sequentially output by the high-speed sampling circuit 141 represents a sampling result obtained by sampling the state of the SPAD output pulse PA0 at each time of the high-speed sampling interval SD1 from the base point of light emission (time t0). More specifically, respective bit values of the latch output pulses PB0′, PB1′, PB2′, PB3′, PB0′, PB1′, PB2′, PB3 PB0′, PB1′, PB2′, PB3, . . . sequentially output from the high-speed sampling circuit 141 represent a High or Low state of the high-speed sampling interval SD1 of the SPAD output pulse PA0 from the base point of light emission (time t0).

Accordingly, as illustrated in a lower part of FIG. 18, the histogram generation circuit 71A generates a histogram by integrating the number of times of High of the SPAD output pulse PA0 at each time of the high-speed sampling interval SD1, and supplies the histogram to the distance calculation unit 72. The distance calculation unit 72 detects the peak value of the histogram on the basis of the histogram data supplied from the histogram generation circuit 71 and calculates the distance to the subject.

Note that, as illustrated in FIG. 18, instead of generating the histogram by integrating the number of times of High of the SPAD output pulse PA0 at each time of the high-speed sampling interval SD1, the number of cycles until the 4-bit latch output pulse [PB0′, PB1′, PB2′, and PB3′] of 250 MHz first becomes High may be counted to generate a histogram of the number of cycles. For example, in an output example of the high-speed sampling circuit 141 in the upper part of FIG. 18, the 4-bit latch output pulse [PB0′, PB1′, PB2′, and PB3′] becomes High for the first time in the seventh cycle, and thus the histogram generation circuit 71A counts up the frequency of the “seventh” cycle by 1. Then, the distance to the subject may be calculated on the basis of the peak value of the histogram of the finally generated number of cycles.

### 11. Processing in iToF Distance Measurement Mode

Next, a case where the measurement mode is the iToF distance measurement mode will be described.

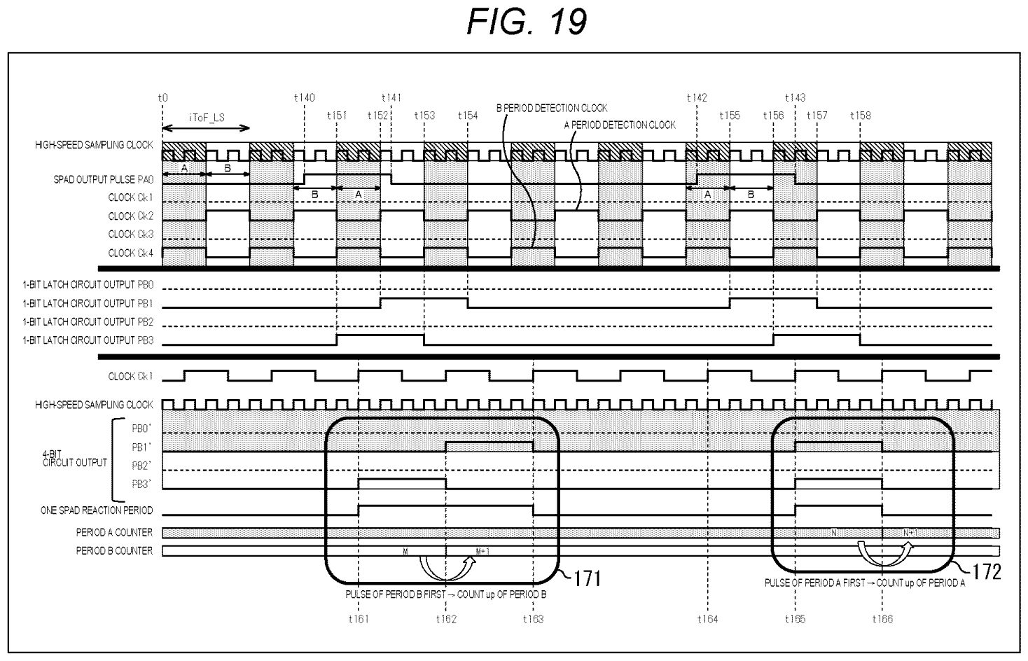

FIG. 19 is a time chart illustrating processing of the high-speed sampling circuit 141 of FIG. 16 and the iToF data processing unit 47 in a case where the measurement mode is the iToF distance measurement mode.

Also in the iToF distance measurement mode in FIG. 19, a sampling clock of a high frequency (high-speed sampling clock) is 1 GHz, and clocks Ck1 to Ck4 of a low frequency are 250 MHz.

Furthermore, the light emission interval iToF_LS of the irradiation light in the iToF distance measurement is four cycles of a 1 GHz high-speed sampling clock, and the high-speed sampling period (low-speed output interval SD2) is the same as the light emission interval iToF_LS of the irradiation light in the iToF distance measurement.

The light emission timing control section 42 divides the light emission interval iToF_LS into two periods of a light emission period A and a stop period B, generates a light emission pulse that alternately repeats the light emission period A and the stop period B, and outputs the light emission pulse to the LD 12. The time at which the light emission timing control section 42 starts light emission is time t0. For example, it is assumed that the SPAD pixel 101 outputs the High SPAD output pulse PA0 in a period from time t140 to time t141 and a period from time t142 to time t143.

In the iToF distance measurement mode, as described above, since it is detected whether the timing at which the SPAD 122 has reacted is in the light emission period A or the stop period B, only two 1-bit latch circuits 161 out of the four 1-bit latch circuits 161A to 161D of the high-speed sampling circuit 141 are used. The remaining two 1-bit latch circuits 161 can stop operation to reduce power consumption. In the example of FIG. 19, 1-bit latch circuits 161B and 161D are used.

The 1-bit latch circuits 161B and 161D detect the reaction of the SPAD 122 at a rising timing of the input clock Ck. The edge of the clock Ck2 rises at the beginning of the stop period B, and thus the 1-bit latch circuit 161B detects the reaction of the SPAD 122 in the light emission period A. The edge of the clock Ck4 rises at the beginning of the light emission period A, and thus the 1-bit latch circuit 161D detects the reaction of the SPAD 122 in the stop period B.

First, processing for the High SPAD output pulse PA0 in the period from time t140 to time t141 will be described. In the SPAD output pulse PA0 in this period, the SPAD 122 has reacted in the stop period B.

At time t151 after time t140, the clock Ck4 input to the 1-bit latch circuit 161D becomes High, and the 1-bit latch circuit 161D detects the High SPAD output pulse PA0 and changes the latch output pulse PB3 to High. Then, at time t153 when the clock Ck4 becomes High next, the 1-bit latch circuit 161D detects the Low SPAD output pulse PA0 and changes the latch output pulse PB3 to Low. Therefore, the latch output pulse PB3 becomes High during the period from time t151 to time t153.

At time t152 after time t151, the clock Ck2 input to the 1-bit latch circuit 161B becomes High, and the 1-bit latch circuit 161B detects the High SPAD output pulse PA0 and changes the latch output pulse PB1 to High. Then, at time t154 when the clock Ck2 becomes High next, the 1-bit latch circuit 161B detects the Low SPAD output pulse PA0 and changes the latch output pulse PB1 to Low. Therefore, the latch output pulse PB1 becomes High during the period from time t152 to time t154.

The 4-bit latch circuit 162 detects the latch output pulses PB1 and PB3 output from the 1-bit latch circuits 161B and 161D, respectively, on the basis of the input clock Ck1, and outputs a 2-bit latch output pulse [PB1′ and PB3′] corresponding to the state to the phase counting circuit 81A.

The latch output pulse PB1 is Low and the latch output pulse PB3 is High at the rise of the clock Ck1 at time t161, and thus the 4-bit latch circuit 162 outputs the 2-bit latch output pulse [PB1′ and PB3′]=[Low and High] to the phase counting circuit 81A.

At the rise of the clock Ck1 at the next time t162, the latch output pulse PB1 is High and the latch output pulse PB3 is Low, and thus the 4-bit latch circuit 162 outputs the 2-bit latch output pulse [PB1′ and PB3′]=[High and Low] to the phase counting circuit 81A.

The phase counting circuit 81A includes a counter that counts each of the number of times of reaction in the light emission period A and the number of times of reaction in the stop period B. A counter that counts the number of times of reaction in the light emission period A is referred to as a period A counter, and a counter that counts the number of times of reaction in the stop period B is referred to as a period B counter.

Like the pulses surrounded by a frame 171, in a case where the latch output pulse PB3′ corresponding to the stop period B first becomes High and the latch output pulse PB1′ corresponding to the light emission period A later becomes High, it indicates that the SPAD 122 has reacted during the stop period B. Accordingly, the phase counting circuit 81A counts up the period B counter by 1 for one SPAD reaction period surrounded by the frame 171.

Next, processing for the High SPAD output pulse PA0 in the period from time t142 to time t143 will be described. In the SPAD output pulse PA0 in this period, the SPAD 122 has reacted in the light emission period A.

At time t155 after time t142, the clock Ck2 input to the 1-bit latch circuit 161B becomes High, and the 1-bit latch circuit 161B detects the High SPAD output pulse PA0 and changes the latch output pulse PB1 to High. Then, at time t157 when the clock Ck2 becomes High next, the 1-bit latch circuit 161B detects the Low SPAD output pulse PA0 and changes the latch output pulse PB1 to Low. Therefore, the latch output pulse PB1 becomes High during the period from time t155 to time t157.

At time t156 after time t155, the clock Ck4 input to the 1-bit latch circuit 161D becomes High, and the 1-bit latch circuit 161D detects the High SPAD output pulse PA0 and changes the latch output pulse PB3 to High. Then, at time t158 when the clock Ck4 becomes High next, the 1-bit latch circuit 161D detects the Low SPAD output pulse PA0 and changes the latch output pulse PB3 to Low. Therefore, the latch output pulse PB3 becomes High during the period from time t156 to time t158.

The 4-bit latch circuit 162 detects the latch output pulses PB1 and PB3 output from the 1-bit latch circuits 161B and 161D, respectively, on the basis of the input clock Ck1, and outputs the 2-bit latch output pulse [PB1′ and PB3′] corresponding to the state to the phase counting circuit 81A.

The latch output pulse PB1 is Low and the latch output pulse PB3 is Low at the rise of the clock Ck1 at time t164, and thus the 4-bit latch circuit 162 outputs the 2-bit latch output pulse [PB1′ and PB3′]=[Low and Low] to the phase counting circuit 81A.

At the rise of the clock Ck1 at the next time t165, the latch output pulse PB1 is High and the latch output pulse PB3 is High, and thus the 4-bit latch circuit 162 outputs the 2-bit latch output pulse [PB1′ and PB3′]=[High and High] to the phase counting circuit 81A.

The latch output pulse PB1 is Low and the latch output pulse PB3 is Low at the rise of the clock Ck1 at the next time t166, and thus the 4-bit latch circuit 162 outputs the 2-bit latch output pulse [PB1′ and PB3′]=[Low and Low] to the phase counting circuit 81A.

Like the pulse surrounded by a frame 172, in a case where the latch output pulse PB1′ corresponding to the light emission period A and the latch output pulse PB3′ corresponding to the stop period B simultaneously become High, or in a case where the latch output pulse PB1′ corresponding to the light emission period A first becomes High and the latch output pulse PB3′ corresponding to the stop period B later becomes High, it is indicated that the SPAD 122 has reacted in the light emission period A. Accordingly, the phase counting circuit 81A counts up the period A counter by 1 for one SPAD reaction period surrounded by the frame 172.

As described above, the phase counting circuit 81A determines whether the SPAD 122 has reacted in the light emission period A or the SPAD 122 has reacted in the stop period B according to whether the latch output pulse PB1′ corresponding to the light emission period A becomes High first or the latch output pulse PB3′ corresponding to the stop period B becomes High first. Then, the phase counting circuit 81A counts the number of times of reaction in the light emission period A and the number of times of reaction in the stop period B by the period A counter and the period B counter, respectively. The distance calculation unit 82 detects the phase difference of the reflected light using the ratio of the counting result and calculates the distance to the subject.

Furthermore, the above-described example is a method of detecting the light reception timing in two phases of a phase of 0 degrees and a phase of 180 degrees with respect to the light emission period A, but in the iToF distance measurement, there is also a method of detecting in four phases of a phase of 0 degrees, a phase of 90 degrees, a phase of 180 degrees, and a phase of 270 degrees. In a case of the method of detecting in four phases, the number of SPAD reactions in each phase is detected using the four 1-bit latch circuits 161A to 161D of the high-speed sampling circuit 141. Alternatively, even in a method of detecting in two phases, detection may be performed by operating four 1-bit latch circuits 161A to 161D at different duty ratios (for example, 75% and 25%).

### 12. Processing in Viewing Mode

Next, a case where the measurement mode is the viewing mode will be described.

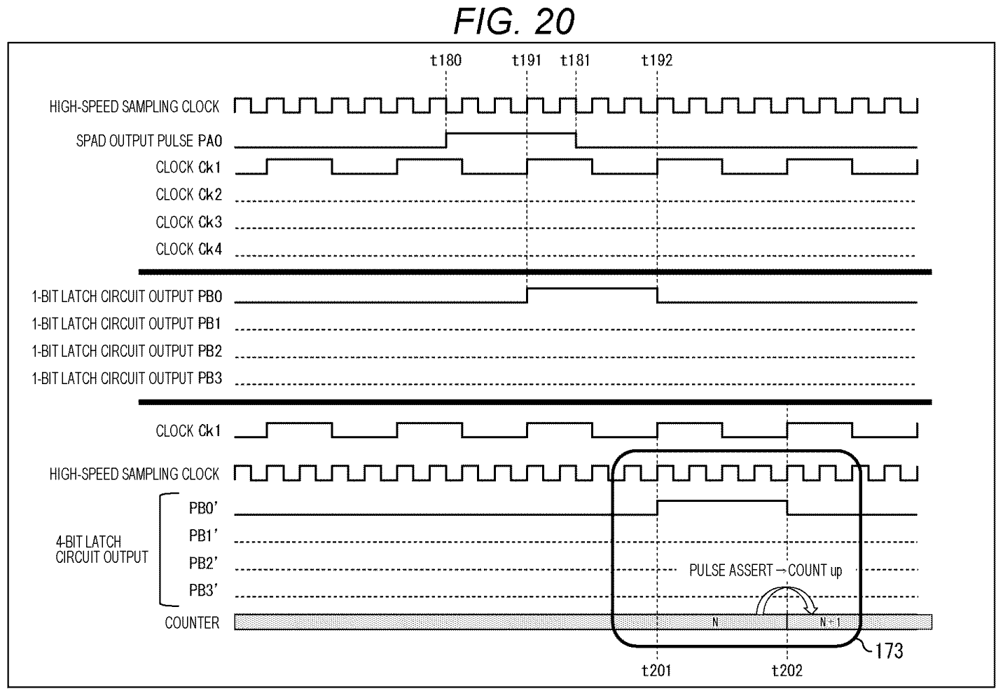

FIG. 20 is a time chart illustrating processing of the high-speed sampling circuit 141 and the viewing data processing unit 48 in FIG. 16 in a case where the measurement mode is the viewing mode.

Also in the viewing mode of FIG. 20, the high frequency sampling clock (high-speed sampling clock) is 1 GHz, and the low-frequency clocks Ck1 to Ck4 are 250 MHz.

In the example of FIG. 20, it is assumed that the High SPAD output pulse PA0 is output in a period from time t180 to time t181.

In the viewing mode, since only the number of times the SPAD 122 has reacted is detected, only one 1-bit latch circuit 161 is used among the four 1-bit latch circuits 161A to 161D of the high-speed sampling circuit 141. The remaining three 1-bit latch circuits 161 can stop operation to reduce power consumption. In the example of FIG. 20, the 1-bit latch circuit 161A is used.

At time t191 after time t180, the clock Ck1 input to the 1-bit latch circuit 161A becomes High, and the 1-bit latch circuit 161A detects the High SPAD output pulse PA0 and changes the latch output pulse PB0 to High. Then, at time t192 when the clock Ck1 becomes High next, the 1-bit latch circuit 161A detects the Low SPAD output pulse PA0 and changes the latch output pulse PB0 to Low. Therefore, the latch output pulse PB0 becomes High during the period from time t191 to time t192.

The 4-bit latch circuit 162 detects the latch output pulse PB0 output from the 1-bit latch circuit 161A on the basis of the input clock Ck1, and outputs the 1-bit latch output pulse PB0′ corresponding to the state thereof to the photon counting circuit 91A.

The latch output pulse PB0 is High at the rise of the clock Ck1 at time t201, and thus the 4-bit latch circuit 162 outputs the 1-bit latch output pulse PB0′=High to the photon counting circuit 91A.

The latch output pulse PB0 is Low (falling) at the rise of the clock Ck1 at the next time t202, and thus the 4-bit latch circuit 162 outputs the 1-bit latch output pulse PB0′=Low to the photon counting circuit 91A.

The photon counting circuit 91A includes a counter that counts the number of times the 1-bit latch output pulse PB0′ supplied from the high-speed sampling circuit 141 is asserted (changed to High). The photon counting circuit 91A counts up the counter by 1 for one SPAD reaction period surrounded by a frame 173. The final counting result is supplied to the image data processing unit 92, and the image data processing unit 92 generates image data in which the counting result is a pixel value (luminance value).

In the examples of the iToF distance measurement mode and the viewing mode described above, the frequency of the high-speed sampling clock is 1 GHz, which is the same as that in the dToF distance measurement mode, but the operation clock frequency of the iToF distance measurement mode and the viewing mode may be changed to the operation clock frequency of the dToF distance measurement mode.

### 13. Second Configuration Example of High-Speed Sampling Circuit

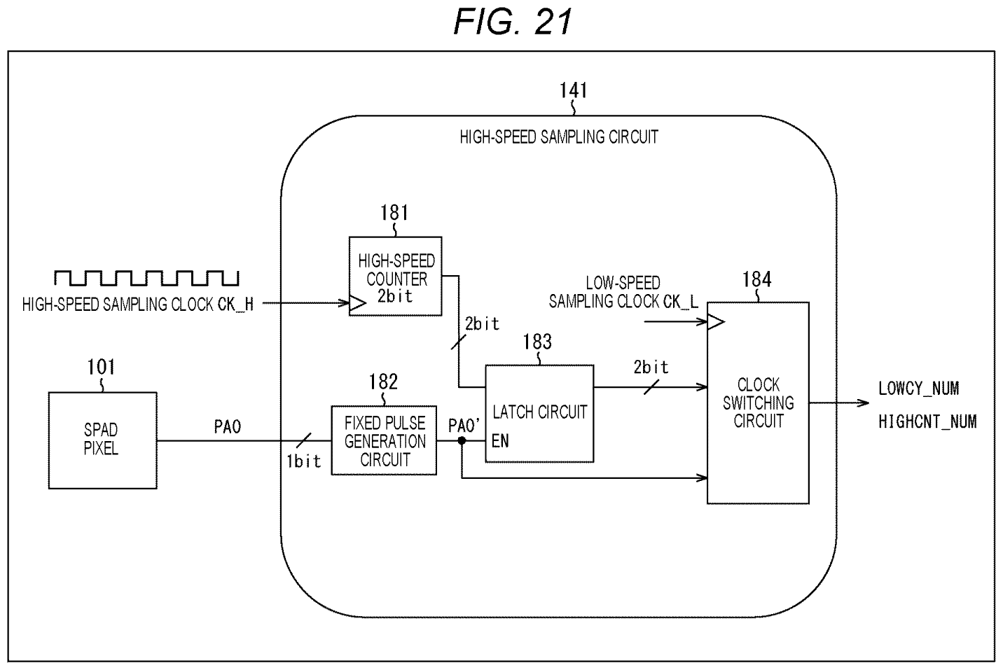

FIG. 21 illustrates a second configuration example of the high-speed sampling circuit 141.

The high-speed sampling circuit 141 in FIG. 21 corresponds to a case of outputting a 4-bit sampling result at a low frequency of ¼ of high-speed sampling in the first configuration example illustrated in FIG. 16.

The high-speed sampling circuit 141 includes a high-speed counter circuit 181, a fixed pulse generation circuit 182, a latch circuit 183, and a clock switching circuit 184.

A high-frequency sampling clock (high-speed sampling clock) CK_H corresponding to the high-speed sampling interval SD1 is input to the high-speed counter circuit 181. The high-speed counter circuit 181 periodically counts only the high-speed sampling period in FIG. 15 with 2 bits on the basis of the high-speed sampling clock CK_H. The high-speed counter circuit 181 supplies the counting result to the latch circuit 183. By setting the count number to a power of 2, a free-run counter that does not require synchronous reset can be used.

The fixed pulse generation circuit 182 detects a rise of the SPAD output pulse PA0 supplied from the SPAD pixel 101, generates a SPAD output pulse PA0′ having a fixed High period, and supplies the SPAD output pulse PA0′ to the latch circuit 183 and the clock switching circuit 184. That is, since the SPAD pixel 101 illustrated in FIG. 5 is a circuit that passively performs quenching and recharging, the length of the High period in which the SPAD output pulse PA0 becomes High in accordance with the detection of photons differs every time. The fixed pulse generation circuit 182 converts the SPAD output pulse PA0 with a variable High period supplied from the SPAD pixel 101 into the SPAD output pulse PA0′ with a fixed High period, and outputs the SPAD output pulse PA0′. The High period can be, for example, one cycle of a low-speed sampling clock CK_L.

The latch circuit 183 latches the 2-bit count value from the high-speed counter circuit 181 on the basis of the SPAD output pulse PA0′ and supplies the count value to the clock switching circuit 184.

The low-speed sampling clock CK_L having a low frequency of ¼ of high-speed sampling is input to the clock switching circuit 184. The clock switching circuit 184 detects the number of low-speed clock cycles LOWCY_NUM and a high-speed count value HIGHCNT_NUM on the basis of the low-speed sampling clock CK_L, and outputs them to the subsequent stage. The number of low-speed clock cycles LOWCY_NUM indicates at which cycle of the low-speed sampling clock CK_L from the light emission start time t0 the assertion of the SPAD output pulse PA0′ is detected. The high-speed count value HIGHCNT_NUM represents latch data (2 bits) of the latch circuit 183 when the SPAD output pulse PA0′ is asserted.

### 14. High-Speed Sampling Processing in dToF Distance Measurement Mode

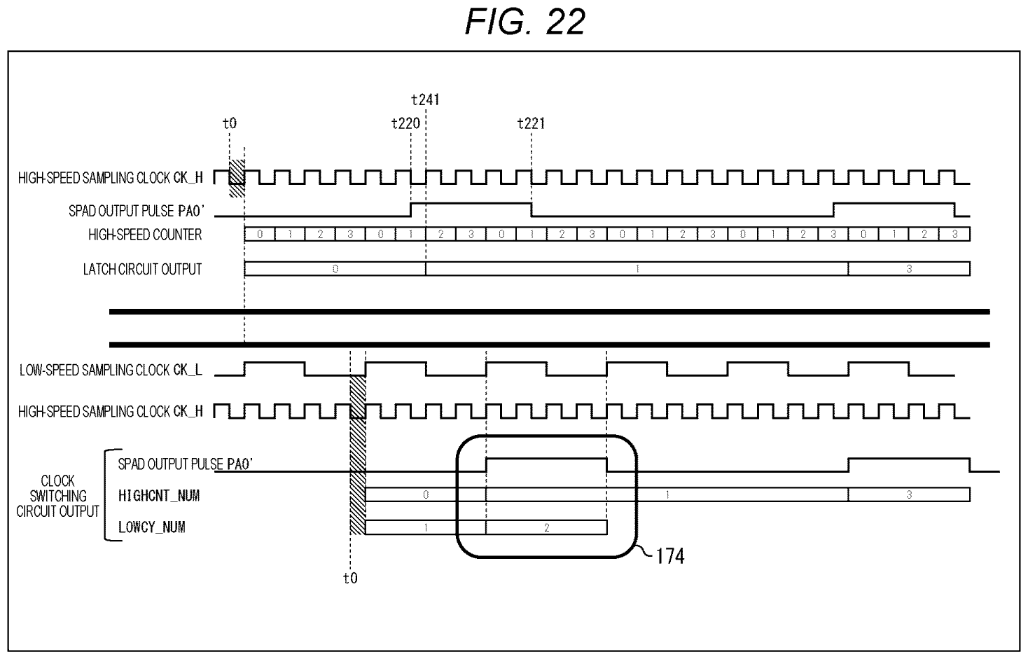

FIG. 22 is a time chart illustrating processing of the high-speed sampling circuit 141 of FIG. 21 in a case where the measurement mode is the dToF distance measurement mode.

In the example of FIG. 22, the high-speed sampling clock CK_H is 1 GHz, and the low-speed sampling clock CK_L is 250 MHz.

A time at which the light emitting unit 13 emits irradiation light, which is a base point of light emission, is defined as time to. It is assumed that the SPAD pixel 101 receives the reflected light of the irradiation light emitted from the light emitting unit 13 at time t0 and outputs the High SPAD output pulse PA0 in a period from time t220 to time t221.

At time t241, which is a rising edge of the first high-speed sampling clock CK_H after the SPAD output pulse PA0′ becomes High, the latch circuit 183 outputs “1”, which is a count value of the high-speed counter 181 at that time, to the clock switching circuit 184.

The clock switching circuit 184 counts the number of low-speed clock cycles LOWCY_NUM according to the low-speed sampling clock CK_L from time t0 at which the light emitting unit 13 emits the irradiation light, and detects and outputs the number of low-speed clock cycles LOWCY_NUM when the SPAD output pulse PA0′ becomes High. Furthermore, the clock switching circuit 184 outputs the count value, which is the output of the latch circuit 183 when the SPAD output pulse PA0′ becomes High, as the high-speed count value HIGHCNT_NUM.

For the assertion of the SPAD output pulse PA0′ surrounded by a frame 174, the SPAD output pulse PA0′ is High when the high-speed counter is 1 in the second cycle of the low-speed sampling clock CK_L from the light emission start time to. Therefore, the clock switching circuit 184 outputs the high-speed count value HIGHCNT_NUM=“1” and the low-speed clock cycle number LOWCY_NUM=“2”.

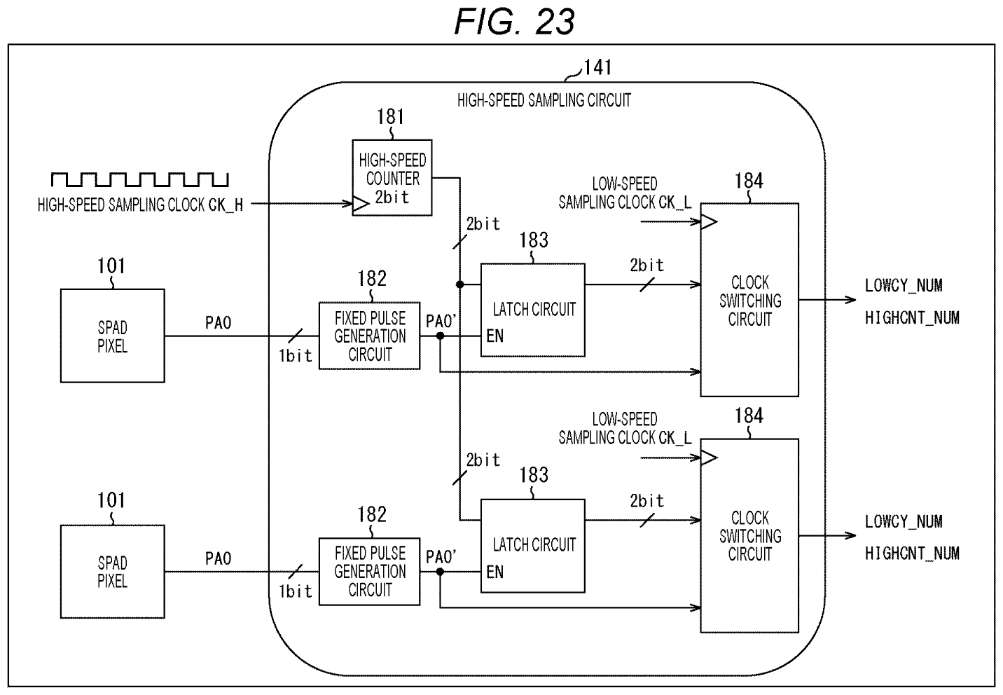

Note that the high-speed counter circuit 181 can be shared and used by a plurality of SPAD pixels 101 as illustrated in FIG. 23.

### 15. Summary of First Embodiment

According to the first embodiment of the distance measuring sensor 11 described above, the dToF distance measurement mode, the iToF distance measurement mode, or the viewing mode is switched in a time division manner, and different measurements according to respective measurement modes can be performed using the SPAD pixels 101 in common. By using the SPAD pixels 101 in common as light receiving pixels, the number of components can be reduced. Circuits other than the measurement mode to be executed can stop the supply of power and clocks. Thus, the power consumption can be reduced. Since the distance measuring sensor 11 operates by switching the measurement mode in the sensor, and the control device 10 only needs to designate the measurement method and transmit the measurement request, the control of the control device 10 becomes simple. By performing the operation according to each measurement mode in a time division manner, it is possible to measure a distance with high accuracy or generate viewing data with high resolution.

In the example described above, the frequency of the high-speed sampling clock in each measurement mode is 1 GHz, which is the same as that in the dToF distance measurement mode, but the frequency of the high-speed sampling clock in the iToF distance measurement mode and the viewing mode may be set lower than that in the dToF distance measurement mode. Thus, the power consumption can be reduced.

In the distance measuring sensor 11, the counting circuit of the phase counting circuit 81 and the counting circuit of the photon counting circuit 91 may be configured as a common circuit and selectively used according to the measurement mode.

Furthermore, in the distance measuring sensor 11, the distance calculation unit 72, the distance calculation unit 82, and the image data processing unit 92 may be omitted, and the histogram data and the counting result of photons may be output to the control device 10 as measurement data. In other words, the calculation of the distance based on the histogram data or the phase counting result and the generation of the viewing data based on the photon counting result may be executed by a digital signal processor (DSP) or the like at a subsequent stage.

The distance measuring system 1 includes one light emitting unit 13 as illustrated in FIG. 1, but may include a plurality of light emitting units 13 and switch the light emitting unit 13 that emits irradiation light according to, for example, the distance measurement mode.

### 16. First Configuration Example of Second Embodiment of Distance Measuring Sensor

Next, a second embodiment of the distance measuring sensor 11 will be described.

The distance measuring sensor 11 according to the first embodiment described above switches the dToF distance measurement mode, the iToF distance measurement mode, or the viewing mode in a time division manner, and outputs the measurement result in each measurement mode in a time division manner.

On the other hand, the distance measuring sensor 11 according to the second embodiment basically drives the dToF distance measurement, generates a histogram on the basis of the SPAD output pulse PA0 output from each SPAD pixel 101, and calculates the distance to the subject. Furthermore, the distance measuring sensor 11 according to the second embodiment also generates image data of viewing (viewing data) by using the generated histogram data, and outputs the image data of viewing at the same time as the distance measurement data of the dToF distance measurement. In other words, in the second embodiment, when the control device 10 transmits only the measurement request to the distance measuring sensor 11 without designating the measurement method, distance measurement data of the dToF distance measurement and viewing data are returned from the distance measuring sensor 11 as a response to the measurement request.

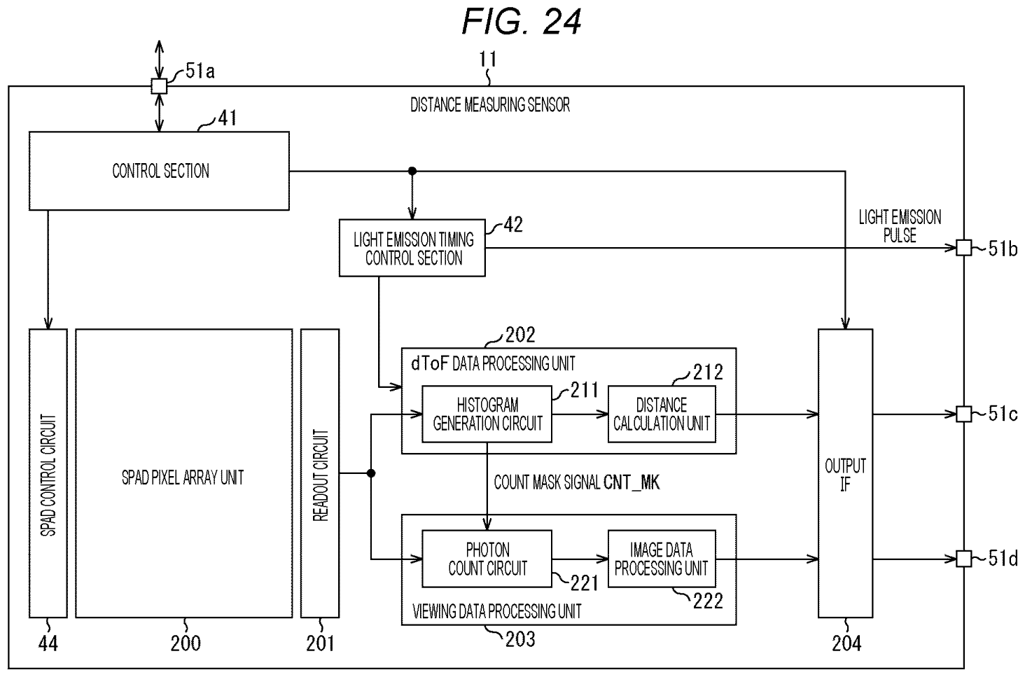

FIG. 24 is a block diagram illustrating a first configuration example of the second embodiment of the distance measuring sensor 11.

In FIG. 24, portions corresponding to those of the first embodiment illustrated in FIG. 2 are denoted by the same reference numerals, and description of the portions will be omitted as appropriate.

The distance measuring sensor 11 includes a control section 41, a light emission timing control section 42, a SPAD control circuit 44, a SPAD pixel array unit 200, a readout circuit 201, a dToF data processing unit 202, a viewing data processing unit 203, an output IF 204, and input-output terminals 51a to 51d.

In the distance measuring sensor 11 of FIG. 24, the control section 41, the light emission timing control section 42, and the SPAD control circuit 44 are common to the distance measuring sensor 11 of FIG. 2. However, since it is not necessary to switch the measurement mode, the control section 41 does not include the mode switching control section 41A.

On the other hand, the SPAD pixel array unit 200, the readout circuit 201, the dToF data processing unit 202, the viewing data processing unit 203, and the output IF 204 are different from the distance measuring sensor 11 in FIG. 2. Furthermore, an input-output terminal 51d is added.

The dToF data processing unit 202 includes a histogram generation circuit 211 and a distance calculation unit 212. The viewing data processing unit 203 includes a photon counting circuit 221 and an image data processing unit 222.

The SPAD pixel array unit 200 is different from the SPAD pixel array unit 43 of the first embodiment illustrated in FIG. 2 in that a red (R), green (G), or blue (B) color filter layer is provided on an incident surface on which light is incident.

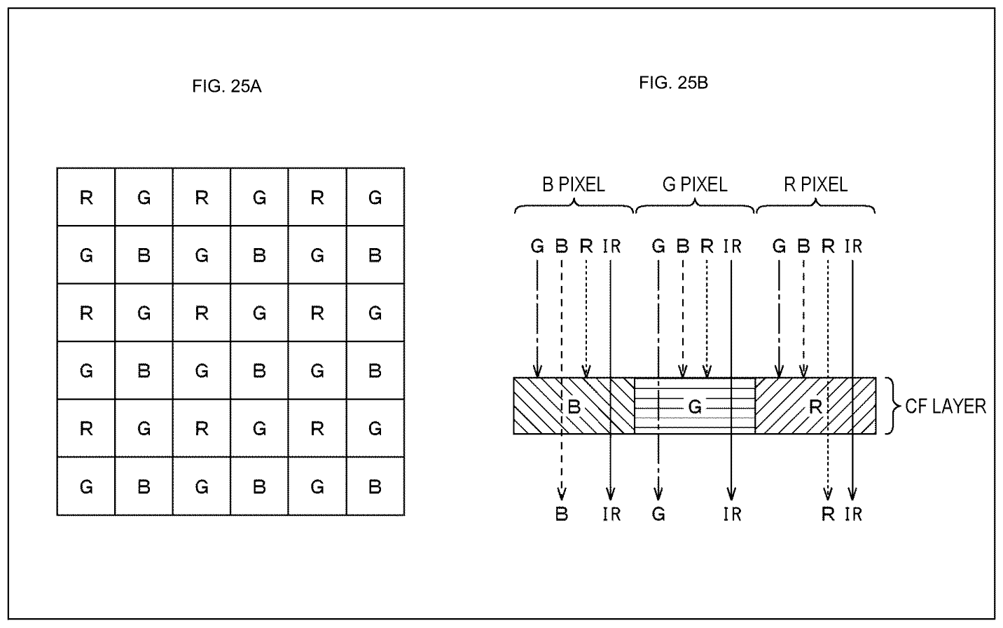

FIG. 25 illustrates an example of a color filter layer provided in the SPAD pixel array unit 200.

The arrangement of the R, G, or B color filter layers is not particularly limited, and for example, the color filter layers are arranged in what is called a Bayer array as illustrated in A of FIG. 25.

As illustrated in B of FIG. 25, the R color filter layer transmits infrared (IR) and R light. The B color filter layer transmits infrared (IR) and B light. The G color filter layer transmits infrared (IR) and G light.

Returning to FIG. 24, the readout circuit 201 supplies the pixel signal (SPAD output pulse PA0) supplied from each SPAD pixel 101 of the SPAD pixel array unit 200 to both the dToF data processing unit 202 and the viewing data processing unit 203.

Similar to the histogram generation circuit 71 in the first embodiment, the histogram generation circuit 211 of the dToF data processing unit 202 creates a histogram of the count value corresponding to the flight time for each pixel on the basis of light emission of irradiation light repeatedly executed a predetermined number of times (for example, several to several hundred times) and light reception of the reflected light, and supplies the created histogram data to the distance calculation unit 212.

Moreover, the histogram generation circuit 211 generates a count mask signal CNT_MK during the generation of the histogram data and supplies the same to the photon counting circuit 221 of the viewing data processing unit 203.

The distance calculation unit 212 performs noise removal, histogram peak detection, and the like on the histogram data supplied from the histogram generation circuit 211. Then, the distance calculation unit 212 calculates the flight time on the basis of a detected peak value of the histogram, calculates the distance to the subject for each pixel from the calculated flight time, and supplies the calculated distance to the output IF 204.

The photon counting circuit 221 of the viewing data processing unit 203 counts the number of times of incidence of photons for each pixel on the basis of the pixel signal (SPAD output pulse PA0) supplied from each SPAD pixel 101 of the SPAD pixel array unit 200. However, the photon counting circuit 221 stops counting photons during a predetermined period in which the count mask signal CNT_MK supplied from the histogram generation circuit 211 is set to High.

The image data processing unit 222 generates viewing data on the basis of a photon counting result measured for each pixel, and supplies the viewing data to the output IF 204.

The output IF 204 simultaneously outputs the distance measurement data supplied from the dToF data processing unit 202 and the viewing data supplied from the viewing data processing unit 203 to the control device 10. The distance measurement data is output from the input-output terminal 51c to the control device 10, and the viewing data is output from the input-output terminal 51d to the control device 10.

In the first configuration example of the second embodiment described above, the distance measurement data and the viewing data may be generated and output in units of one pixel, or may be generated and output in units of a plurality of pixels, which is similar to the first embodiment described above.

### 17. Generation of Count Mask Signal

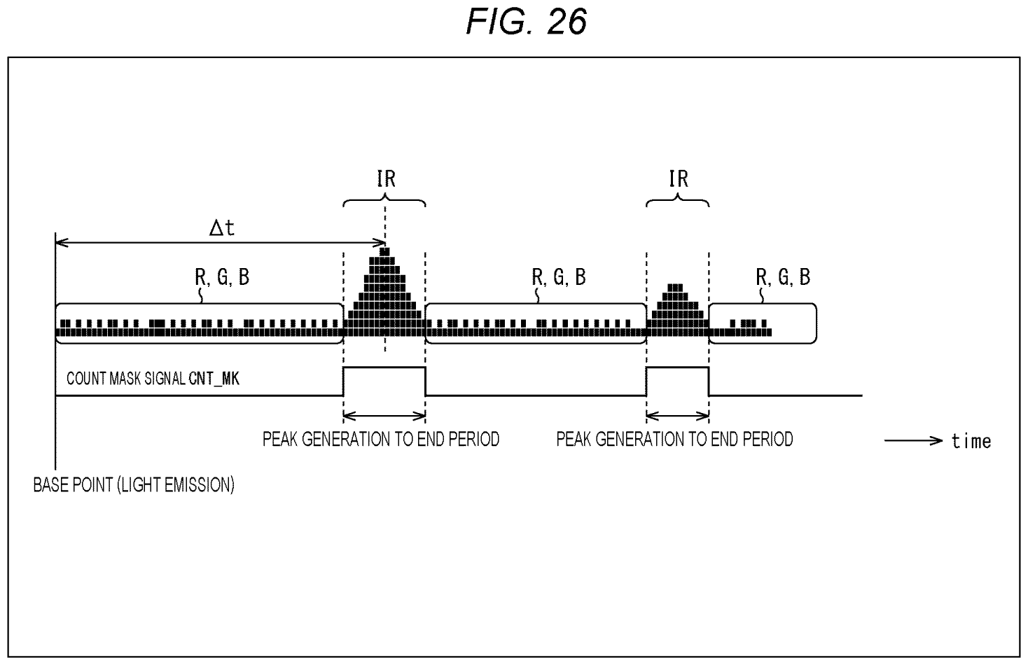

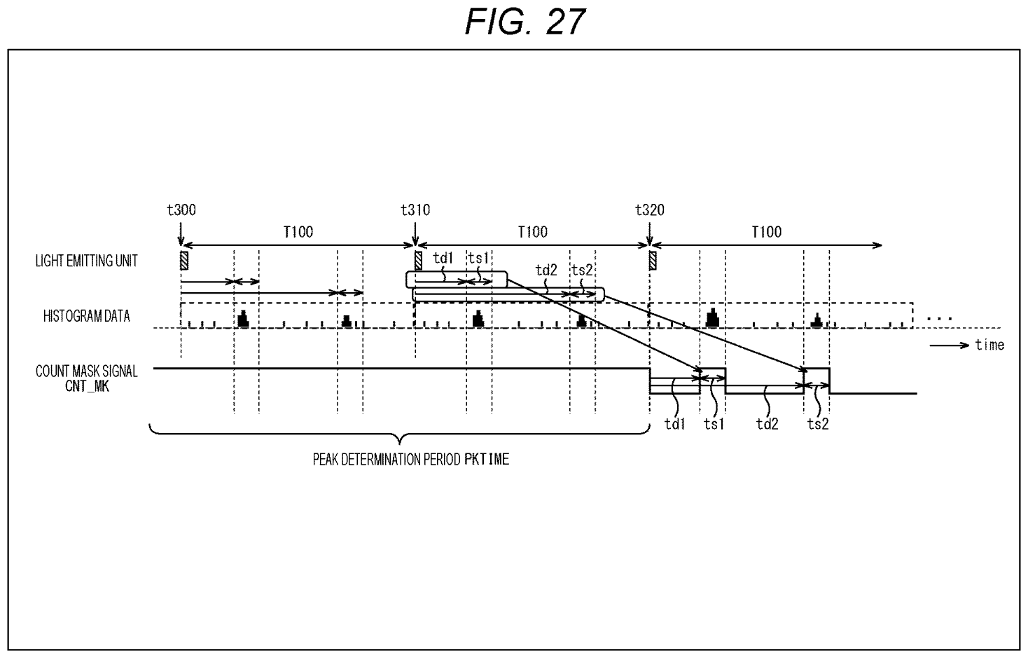

The generation of the count mask signal CNT_MK performed by the histogram generation circuit 211 will be described with reference to FIGS. 26 and 27.

As described with reference to FIG. 25, since the infrared light is transmitted through any of the R, G, and B color filter layers, the infrared light is received by all the SPAD pixels 101 of the SPAD pixel array unit 200. Most of the received infrared light is reflected light of the irradiation light emitted from the light emitting unit 13, and is concentrated on Δt time according to the distance DS to the subject as illustrated in FIG. 26. Therefore, in a case where the histogram is generated, the light in the period (hereinafter referred to as a peak period) from the generation to the end of the peak of the histogram corresponds to the infrared light, and the light other than the peak period corresponds to the light of R, G, and B.

Accordingly, the histogram generation circuit 211 detects a peak period from the generation to the end of the peak, generates the count mask signal CNT_MK in which the detected peak period is High, and supplies the count mask signal CNT_MK to the photon counting circuit 221. For example, by detecting a peak value (maximum value) for which the count value of the histogram is equal to or more than a first threshold Vth1, the peak period can be detected as a section including the peak value with the count value equal to or more than a second threshold Vth2 (Vth1>Vth2).

Specifically, the distance measuring sensor 11 generates a histogram by repeating emission and reception of the irradiation light multiple times (for example, several to several hundred times), and as illustrated in FIG. 27, a peak determination period PKTIME for detecting a peak period of the histogram is provided a first few times.

The example of FIG. 27 is, for example, an example in which the first two times of repetition of the irradiation light 100 times to generate the histogram are set as the peak determination period PKTIME. In FIG. 27, times t300, t310, and t320 are times when the irradiation light is emitted, and time T100 between the light emission times represents a light emission interval.

With the peak determination period PKTIME, the histogram generation circuit 211 detects that the ts1 period after the lapse of td1 time from the light emission start time and the ts2 period after the lapse of td2 time are peak periods. Then, the histogram generation circuit 211 generates the count mask signal CNT_MK in which the ts1 period and the ts2 period are set to be High in accordance with the light emission timing of the irradiation light after time t320, which is the third time, and supplies the count mask signal CNT_MK to the photon counting circuit 221. During a period in which the count mask signal CNT_MK is High, the photon counting circuit 221 does not count up the count value of photons even if the pixel signal (SPAD output pulse PA0) from the SPAD pixel 101 becomes High. That is, the counting of photons is stopped during a period in which the count mask signal CNT_MK is High.

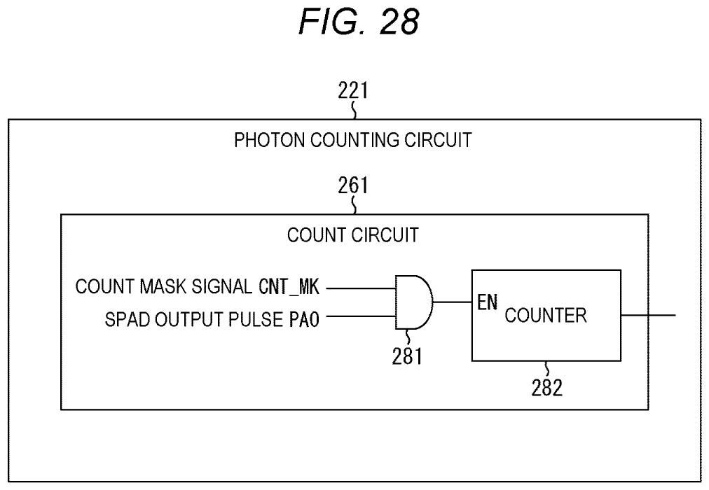

FIG. 28 is a block diagram illustrating a schematic configuration of the counting circuit 261 provided for each unit in which the photon counting circuit 221 of the viewing data processing unit 203 generates a histogram.

The counting circuit 261 includes an AND circuit 281 and a counter circuit 282, and the count mask signal CNT_MK and the SPAD output pulse PA0 from the SPAD pixel 101 are input to the AND circuit 281.

The AND circuit 281 executes an AND operation of the count mask signal CNT_MK and the SPAD output pulse PA0, and outputs the execution result to the counter circuit 282. The counter circuit 282 counts up the count value by 1 every time the High signal is input from the AND circuit 281, and supplies the counting result to the image data processing unit 222 when the measurement is completed.

### 18. Modification of First Configuration Example of Second Embodiment

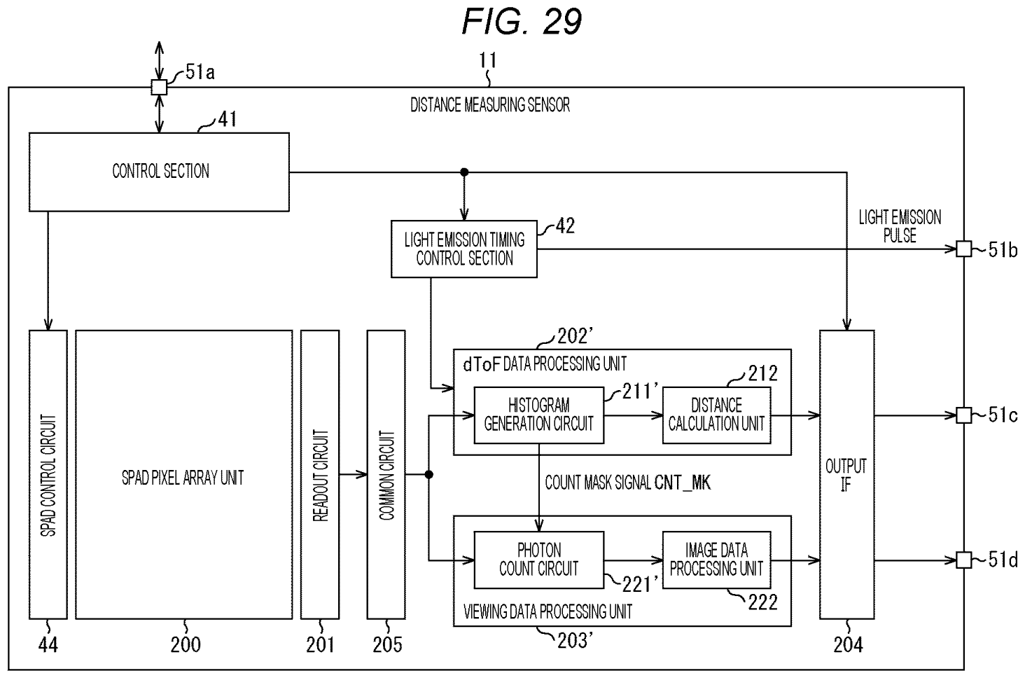

FIG. 29 is a block diagram illustrating a modification of the first configuration example according to the second embodiment illustrated in FIG. 24.

When the modification of FIG. 29 is compared with the configuration illustrated in FIG. 24, a common circuit 205 is newly added between the readout circuit 201, the dToF data processing unit 202′, and the viewing data processing unit 203′. A circuit that executes common processing in the dToF data processing unit 202 and the viewing data processing unit 203 illustrated in FIG. 24 is provided as a common circuit 205 in a preceding stage thereof. The execution result of the common circuit 205 is supplied to the histogram generation circuit 211′ of the dToF data processing unit 202′ and the photon counting circuit 221′ of the viewing data processing unit 203′. For example, the configuration of the high-speed sampling circuit 141 employed in the second configuration example of the first embodiment in FIG. 13 can be employed as the configuration of the common circuit 205.

### 19. Second Configuration Example of Second Embodiment of Distance Measuring Sensor

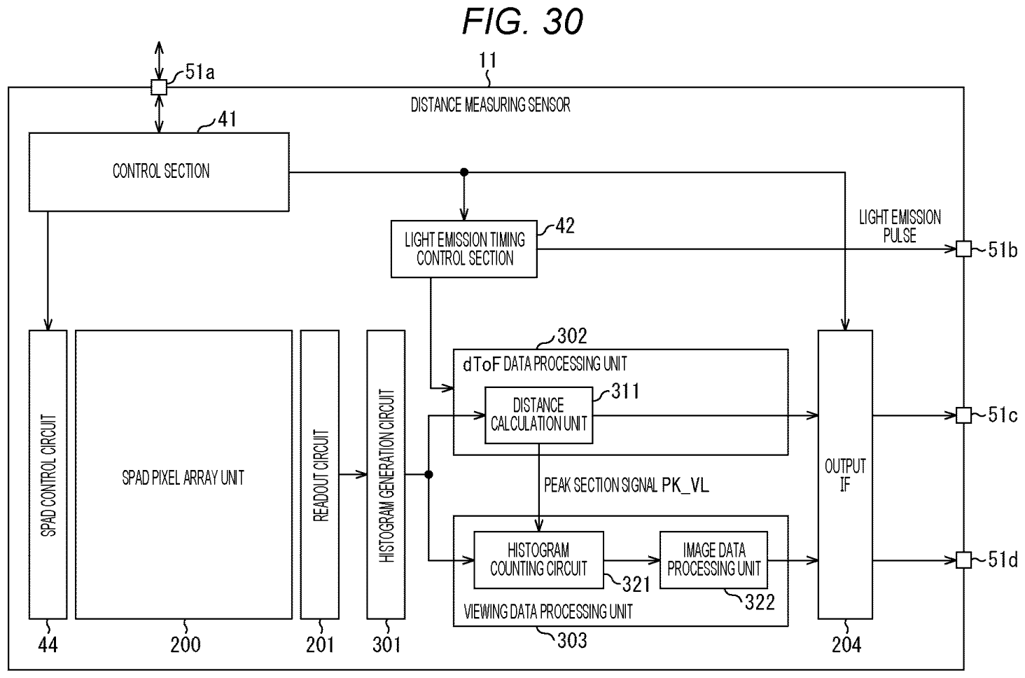

FIG. 30 is a block diagram illustrating a second configuration example of the second embodiment of the distance measuring sensor 11.

In FIG. 30, portions corresponding to those in the first configuration example of the second embodiment illustrated in FIGS. 24 and 29 are denoted by the same reference numerals, and the description thereof will be appropriately omitted.

The distance measuring sensor 11 in FIG. 30 includes the control section 41, the light emission timing control section 42, the SPAD control circuit 44, the SPAD pixel array unit 200, the readout circuit 201, a histogram generation circuit 301, a dToF data processing unit 302, a viewing data processing unit 303, the output IF 204, and the input-output terminals 51a to 51d.

When the second configuration example of FIG. 30 is compared with the first configuration example illustrated in FIG. 24, a histogram generation circuit 301 is newly provided at a subsequent stage of the readout circuit 201. Similar to the histogram generation circuit 211′ of FIG. 24, the histogram generation circuit 301 generates a histogram for each pixel on the basis of the pixel signal (SPAD output pulse PA0) supplied from the readout circuit 201 and supplies generated histogram data to the dToF data processing unit 302 and the viewing data processing unit 303.

Furthermore, in the second configuration example of FIG. 30, a dToF data processing unit 302 and a viewing data processing unit 303 are provided instead of the dToF data processing unit 202 and the viewing data processing unit 203 in the first configuration example illustrated in FIG. 24. In the first configuration example, the count mask signal CNT_MK is supplied from the dToF data processing unit 202 to the viewing data processing unit 203, but in the second configuration example, a peak section signal PK_VL is supplied from the dToF data processing unit 302 to the viewing data processing unit 303.

The dToF data processing unit 302 includes a distance calculation unit 311. The distance calculation unit 311 performs noise removal, histogram peak detection, and the like on the histogram data supplied from the histogram generation circuit 301. Then, the distance calculation unit 311 calculates the flight time on the basis of a detected peak value of the histogram, calculates the distance to the subject for each pixel from the calculated flight time, and supplies the calculated distance to the output IF 204.

Furthermore, the distance calculation unit 311 generates a peak section signal PK_VL in which the peak period of the histogram is High from the histogram data supplied from the histogram generation circuit 301, and supplies the peak section signal PK_VL to the viewing data processing unit 303.

The viewing data processing unit 303 includes a histogram counting circuit 321 and an image data processing unit 322. The histogram counting circuit 321 counts the number of photons corresponding to the light of R, G, and B for each pixel on the basis of the histogram data supplied from the histogram generation circuit 301 and the peak section signal PK_VL, and supplies the counting result to the image data processing unit 322.

The image data processing unit 322 generates viewing data on the basis of a photon counting result measured for each pixel, and supplies the viewing data to the output IF 204.

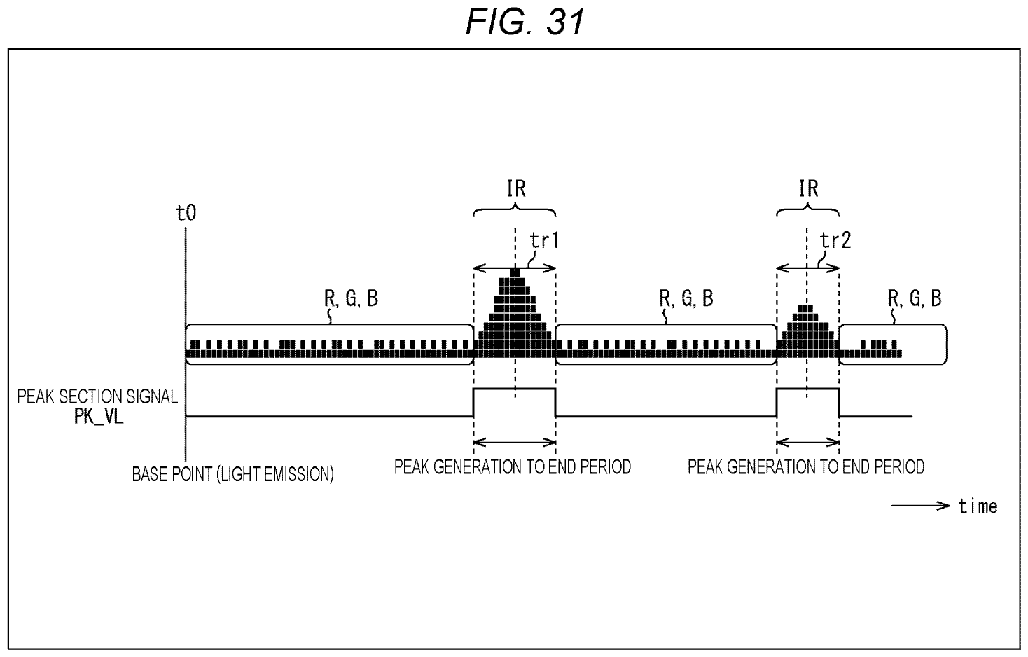

The peak section signal PK_VL generated by the distance calculation unit 311 and the processing of the histogram counting circuit 321 will be described with reference to FIG. 31.

As illustrated in FIG. 31, the histogram data supplied from the histogram generation circuit 301 to the distance calculation unit 311 and the histogram counting circuit 321 is divided into IR light received intensively in a peak period from the occurrence to the end of the peak and light of R, G, or B received in other periods.

The distance calculation unit 311 of the dToF data processing unit 302 detects the peak periods tr1 and tr2 from the histogram data, generates the peak section signal PK_VL in which the detected peak periods tr1 and tr2 become High, and supplies the peak section signal PK_VL to the viewing data processing unit 303.

The histogram data and the peak section signal PK_VL are supplied to the histogram counting circuit 321 of the viewing data processing unit 303 for each pixel. The histogram counting circuit 321 supplies a value obtained by adding data other than the peak period tr in which the peak section signal PK_VL is High among all the data of the histogram data supplied from the histogram generation circuit 301 to the image data processing unit 322 as a photon counting result.

In the second embodiment, the first configuration example illustrated in FIGS. 24 and 29 and the second configuration example of FIG. 30 are common in that the counting result of photons incident in each SPAD pixel 101 is classified into a counting result of IR light and a counting result of RGB light, and the viewing data processing unit 203 or 303 generates the viewing data on the basis of only the counting result of the RGB light.

On the other hand, in the first configuration example, the histogram generation circuit 211 of the dToF data processing unit 202 generates the count mask signal CNT_MK during the generation of the histogram and supplies the count mask signal CNT_MK to the viewing data processing unit 203, whereas in the second configuration example, the peak section signal PK_VL is generated on the basis of the generated histogram data and supplied to the viewing data processing unit 303. That is, the count mask signal CNT_MK is a signal issued during the generation of the histogram, whereas the peak section signal PK_VL is a signal issued after the generation of the histogram.

The second configuration example can also be said to be a configuration in which the histogram generation circuit 301 is provided as the common circuit 205 of the modification of the first configuration example illustrated in FIG. 29, and the circuit range that can be shared is large. Furthermore, since the histogram generation circuit 301 and the histogram counting circuit 321 do not operate simultaneously, the power consumption can be reduced.

### 20. Summary of Second Embodiment

According to the second embodiment of the distance measuring sensor 11 described above, it is possible to simultaneously generate and output distance measurement data by dToF distance measurement and viewing data on the basis of the pixel signal from the SPAD pixel 101. That is, different measurements can be simultaneously achieved using the SPAD pixel 101 in common as light receiving pixels. By using the SPAD pixel 101 in common, the number of components can be reduced.

In the second embodiment, when the control device 10 transmits the measurement request for requesting execution of measurement to the distance measuring sensor 11 without specifying the measurement method, the distance measuring sensor 11 returns distance measurement data of dToF distance measurement and viewing data as a response to the measurement request. Therefore, the control device 10 can obtain the distance measurement data and the viewing data only by the measurement request without worrying about the measurement mode.

Also in the second embodiment, the distance calculation unit 212 and the image data processing unit 222, or the distance calculation unit 311 and the image data processing unit 322 may be omitted, and the histogram data and the counting result of photons may be output to the control device 10 as measurement data.

Also in the second embodiment, the calculation of the histogram data and the calculation of the distance to the subject based on the histogram data may be performed not in units of one pixel but in units of a plurality of pixels. In addition, in a case where the histogram data is generated in units of groups with a plurality of adjacent pixels as one group, color filters of the same color may be, for example, arranged in units of groups such as arranging the color filter layers of R, G, and B in a Bayer array in units of four pixels of 2×2. In a case where the histogram data is generated in the units of groups including a plurality of adjacent pixels, the data amount can be compressed, and thus the first configuration example in which the photon counting is ended simultaneously with the completion of the histogram data is preferable.

In the second embodiment, both the distance measurement data based on the histogram data and the viewing data can be simultaneously generated and output, but the output timing may be sequential output from one input-output terminal 51c or 51d in a time division manner as in the first embodiment.

### 21. Configuration Example of Electronic Device

The above-described distance measuring system 1 can be mounted on, for example, electronic devices such as a smartphone, a tablet terminal, a mobile phone, a personal computer, a game device, a television receiver, a wearable terminal, a digital still camera, and a digital video camera.

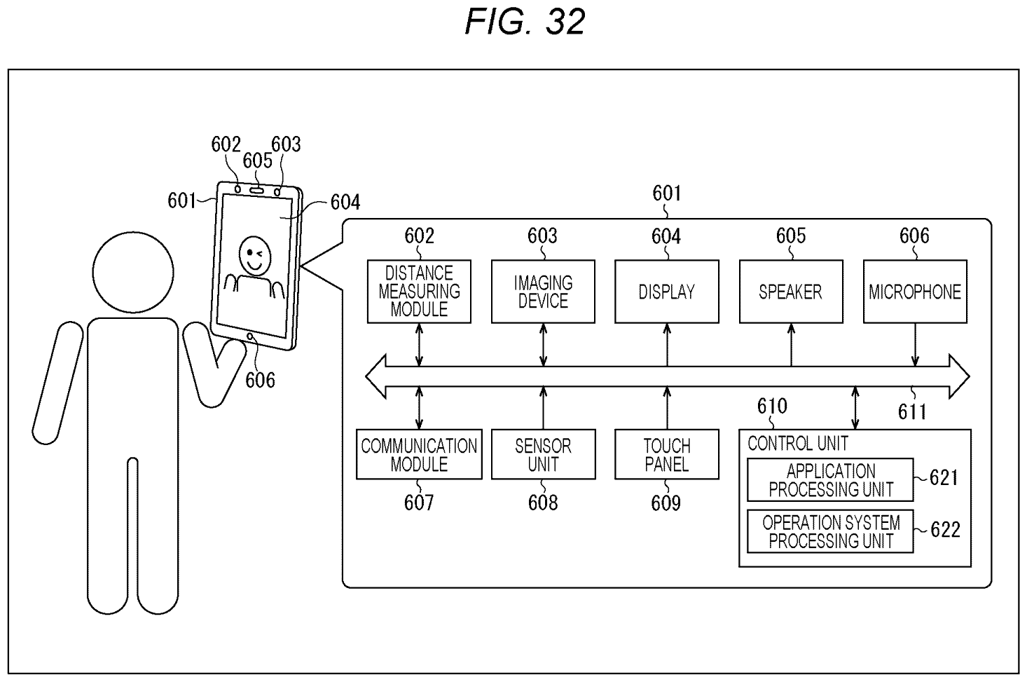

FIG. 32 is a block diagram illustrating a configuration example of a smartphone in which the above-described distance measuring system 1 is mounted as a distance measuring module.

As illustrated in FIG. 32, a smartphone 601 is configured by connecting a distance measuring module 602, an imaging device 603, a display 604, a speaker 605, a microphone 606, a communication module 607, a sensor unit 608, a touch panel 609, and a control unit 610 via a bus 611. Furthermore, the control unit 610 has functions as an application processing section 621 and an operation system processing section 622 by the CPU executing a program.

The distance measuring system 1 of FIG. 1 is applied to the distance measuring module 602. For example, the distance measuring module 602 is arranged in front of the smartphone 601, and performs distance measurement for the user of the smartphone 601, so that the depth value of the surface shape of the face, hand, finger, or the like of the user can be output as a distance measurement result.

The imaging device 603 is arranged in front of the smartphone 601, and performs imaging with the user of the smartphone 601 as a subject to acquire an image in which the user is captured. Note that, although not illustrated, a configuration may be employed in which the imaging device 603 is also disposed on the back surface of the smartphone 601.

The display 604 displays an operation screen for performing processing by the application processing section 621 and the operation system processing section 622, an image captured by the imaging device 603, and the like. The speaker 605 and the microphone 606 output the voice of the other party and collect the voice of the user, for example, when making a call using the smartphone 601.

The communication module 607 performs communication via a communication network. The sensor unit 608 senses speed, acceleration, proximity, and the like, and the touch panel 609 acquires a touch operation by the user on an operation screen displayed on the display 604.

The application processing section 621 performs processing for providing various services by the smartphone 601. For example, the application processing section 621 can perform processing of creating a face by computer graphics virtually reproducing the expression of the user on the basis of a depth supplied from the distance measuring module 602 and displaying the face on the display 604. Furthermore, the application processing section 621 can perform processing of creating three-dimensional shape data of an arbitrary three-dimensional object on the basis of the depth supplied from the distance measuring module 602, for example.

The operation system processing section 622 performs processing for achieving basic functions and operations of the smartphone 601. For example, the operation system processing section 622 can perform processing of authenticating the user's face, and unlocking the smartphone 601 on the basis of the depth value supplied from the distance measuring module 602. Furthermore, the operation system processing section 622 can perform, for example, processing of recognizing a gesture of the user on the basis of the depth value supplied from the distance measuring module 602, and processing of inputting various operations according to the gesture.

In the smartphone 601 configured as described above, by applying the above-described distance measuring system 1 as a distance measuring module, for example, a distance to a predetermined object as a subject can be measured and output as distance measurement data. Furthermore, in the viewing mode, viewing data can also be output.

### 22. Application Example to Mobile Body

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a ship, a robot, and the like.

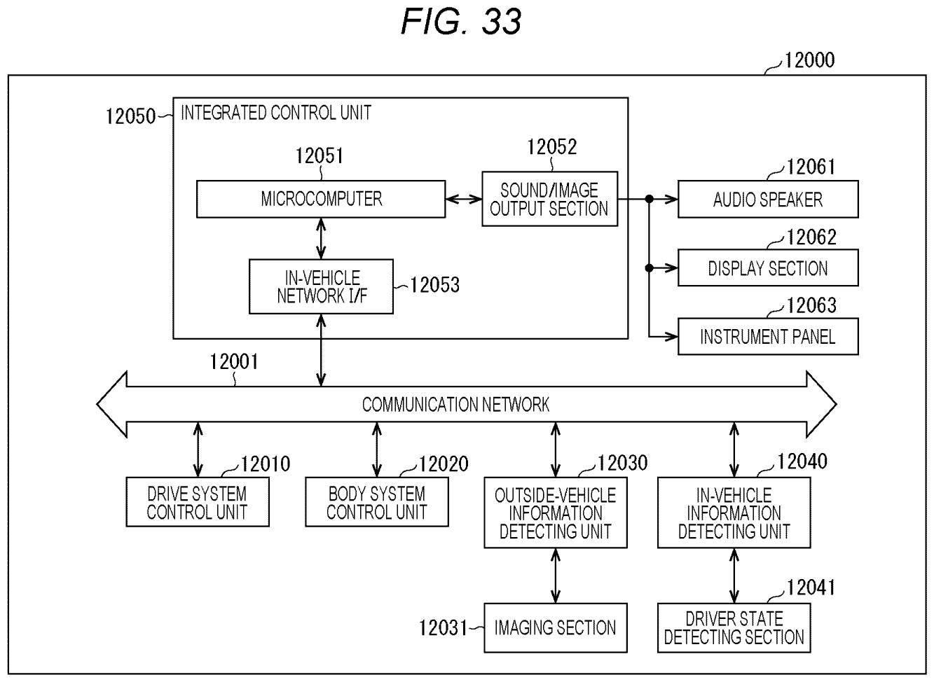

FIG. 33 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 33, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 33, an audio speaker 12061, a display section 12062, and an instrument panel 12063 are illustrated as the output device. The display section 12062 may, for example, include at least one of an on-board display and a head-up display.

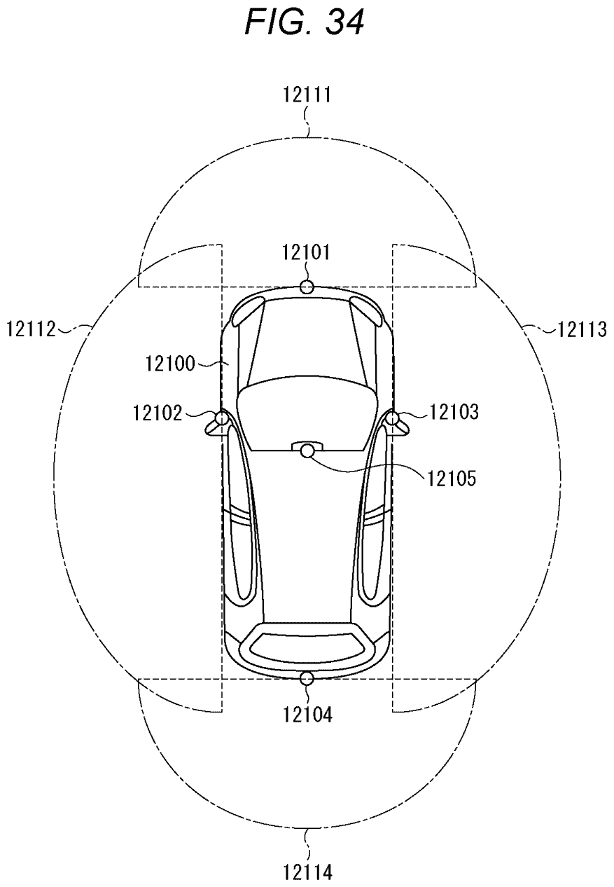

FIG. 34 is a diagram depicting an example of the installation position of the imaging section 12031.

In FIG. 34, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a signal, a traffic sign, a lane, or the like.

Incidentally, FIG. 34 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure can be applied to the imaging section 12031 among the configurations described above. Specifically, the above-described distance measuring system 1 can be applied as the imaging section 12031. By applying the technology according to the present disclosure to the imaging section 12031, it is possible to acquire distance information by both dToF distance measurement and iToF distance measurement. Furthermore, it is possible to reduce driver's fatigue and increase the safety of the driver and the vehicle by using the obtained captured image and distance information.

The embodiments of the present technology are not limited to the above-described embodiments, and various modifications are possible without departing from the gist of the present technology.

The plurality of present technologies which has been described in the present description can be each implemented independently as a single unit as long as no contradiction occurs. Of course, any plurality of the present technologies can also be used and implemented in combination. For example, part or all of the present technologies described in any of the embodiments can be implemented in combination with part or all of the present technologies described in other embodiments. Furthermore, part or all of any of the above-described present technologies can be implemented by using together with another technology that is not described above.

Further, for example, a configuration described as one device (or processing section) may be divided and configured as a plurality of devices (or processing sections). Conversely, configurations described above as a plurality of devices (or processing units) may be combined and configured as one device (or processing unit). In addition, a configuration other than those described above may be added to the configuration of each device (or each processing unit). Moreover, if the configuration and operation of the entire system are substantially the same, a part of the configuration of a certain device (or processing unit) may be included in the configuration of another device (or another processing unit).

Moreover, in the present description, a system means a set of a plurality of components (devices, modules (parts), and the like), and it does not matter whether or not all components are in the same housing. Therefore, both of a plurality of devices housed in separate housings and connected via a network and a single device in which a plurality of modules is housed in one housing are systems.

Note that the effects described in the present description are merely examples and are not limited, and effects other than those described in the present description may be provided.

Note that the present technology can have the following configurations.

(1)

A distance measuring sensor, including:
a single photon avalanche diode (SPAD) pixel including a SPAD as a photoelectric conversion element;
a time-of-flight (ToF) data processing unit that generates and outputs distance measurement data by a ToF method on the basis of a pixel signal output from the SPAD pixel; and
a viewing data processing unit that generates and outputs viewing data on the basis of a pixel signal output from the SPAD pixel.

(2)

The distance measuring sensor according to (1) above, in which
the viewing data processing unit counts a number of times the SPAD has reacted within a predetermined measurement period.

(3)

The distance measuring sensor according to (1) or (2) above, further including
a mode switching control section that switches a measurement mode, in which
the mode switching control section switches, in a time division manner, a distance measurement mode in which the ToF data processing unit performs processing and a viewing mode in which the viewing data processing unit performs processing.

(4)

The distance measuring sensor according to any one of (1) to (3) above, further including
an output unit that outputs either the distance measurement data from the ToF data processing unit or the viewing data from the viewing data processing unit according to a measurement mode.

(5)

The distance measuring sensor according to any one of (1) to (4) above, in which
the ToF data processing unit includes
a direct ToF (dToF) data processing unit that generates and outputs the distance measurement data by a direct ToF method, and
an indirect ToF (iToF) data processing unit that generates and outputs the distance measurement data by an indirect ToF method.

(6)

The distance measuring sensor according to (5) above, further including
an output unit that outputs any one of the distance measurement data from the dToF data processing unit, the distance measurement data from the iToF data processing unit, or the viewing data from the viewing data processing unit according to a measurement mode.

(7)

The distance measuring sensor according to (5) or (6) above, in which
the iToF data processing unit counts a number of times the SPAD has reacted in a first period having a same phase as a light emission timing of irradiation light and a number of times the SPAD has reacted in a second period having a phase obtained by inverting the light emission timing of the irradiation light.

(8)

The distance measuring sensor according to any one of (5) to (7) above, further including
a sampling circuit that outputs an n-bit (n>1) sampling result obtained by sampling the pixel signal of one bit output from the SPAD pixel at a first frequency at a second frequency lower than the first frequency.

(9)

The distance measuring sensor according to (8) above, in which
a sampling interval at which sampling is performed at the first frequency is a sampling interval in a direct ToF measurement mode,
a light emission interval of irradiation light in an indirect ToF measurement mode is a multiple of the sampling interval of the first frequency, and
an output interval at which the n-bit sampling result is output at the second frequency is same as or a multiple of the light emission interval of the irradiation light in the indirect ToF measurement mode.

(10)

The distance measuring sensor according to (8) or (9) above, in which
the sampling circuit includes
n first latch circuits that latch the pixel signal of one bit output from the SPAD pixel at the second frequency, and
a second latch circuit that latches outputs of the n first latch circuits at the second frequency to output the n-bit sampling result.

(11)

The distance measuring sensor according to any one of (8) to (10) above, in which
the dToF data processing unit generates a histogram according to the n-bit sampling result.

(12)

The distance measuring sensor according to any one of (8) to (11) above, in which
the dToF data processing unit generates a histogram according to a number of cycles until the n-bit sampling result becomes High.

(13) The distance measuring sensor according to any one of (10) to (12) above, in which
the iToF data processing unit determines whether the SPAD has reacted in a first period having a same phase as a light emission timing of irradiation light or the SPAD has reacted in a second period having a phase obtained by inverting the light emission timing of the irradiation light according to whether one of the two first latch circuits becomes High first or the other becomes High first.

(14)

The distance measuring sensor according to any one of (10) to (13) above, in which
the viewing data processing unit counts a number of times of becoming High in one of the first latch circuits.

(15)

The distance measuring sensor according to (5) above, further including:
a latch circuit that latches a count value of n bits (n>1) at a first frequency on the basis of the pixel signal of one bit output from the SPAD pixel; and
a low sampling circuit that outputs a number of cycles and the count value when the pixel signal becomes High at a second frequency lower than the first frequency.

(16)

The distance measuring sensor according to (1) above, in which
processing in which the ToF data processing unit generates and outputs the distance measurement data on the basis of the pixel signal output from the SPAD pixel and processing in which the viewing data processing unit generates and outputs the viewing data are simultaneously executed.

(17)

The distance measuring sensor according to (16) above, in which
a plurality of the SPAD pixels is arranged in a matrix, and
each of a plurality of the SPAD pixels is provided with a red (R), green (G), or blue (B) color filter layer.

(18)

The distance measuring sensor according to (16) or (17) above, in which
the ToF data processing unit generates a histogram on the basis of the pixel signal output from the SPAD pixel and generates a count mask signal indicating a peak period of the histogram, and
the viewing data processing unit stops counting photons for a predetermined period on the basis of the count mask signal and generates the viewing data.

(19)

The distance measuring sensor according to any one of (16) to (17) above, further including
a histogram generation circuit that generates a histogram on the basis of the pixel signal output from the SPAD pixel, in which
the ToF data processing unit generates a peak section signal indicating a peak section of the histogram on the basis of the histogram supplied from the histogram generation circuit, and
the viewing data processing unit adds data of other than the peak section on the basis of the peak section signal and generates the viewing data.

(20)

A distance measuring system, including:
a light emitting unit that emits irradiation light;
a distance measuring sensor that receives reflected light in which the irradiation light is reflected by an object, in which
the distance measuring sensor includes:
a single photon avalanche diode (SPAD) pixel including a SPAD as a photoelectric conversion element;
a time-of-flight (ToF) data processing unit that generates and outputs distance measurement data by a ToF method on the basis of a pixel signal output from the SPAD pixel; and
a viewing data processing unit that generates and outputs viewing data on the basis of a pixel signal output from the SPAD pixel.

### REFERENCE SIGNS LIST

1 Distance measuring system
11 Distance measuring sensor
41 Control section
41A Mode switching control section
42 Light emission timing control section
43 SPAD pixel array unit
44 SPAD control circuit
45 Readout circuit
46 dToF data processing unit
47 iToF data processing unit
48 Viewing data processing unit
49 Selection unit
51a to 51c Input-output terminal
71, 71A Histogram generation circuit
72 Distance calculation unit
81, 81A Phase counting circuit
82 Distance calculation unit
91, 91A Photon counting circuit
92 Image data processing unit
101 SPAD pixel
121 SPAD
141 High-speed sampling circuit
161A (161A to 161D) 1-bit latch circuit
162 4-bit latch circuit
PKTIME Peak determination period
PK_VL Peak section signal
181 High-speed counter circuit
182 Fixed pulse generation circuit
183 Latch circuit
184 Clock switching circuit
200 SPAD pixel array unit
201 Readout circuit
202, 202′ dToF data processing unit
203, 203′ Viewing data processing unit
205 Common circuit
211 Histogram generation circuit
212 Distance calculation unit
221 Photon counting circuit
222 Image data processing unit
301 Histogram generation circuit
302 dToF data processing unit
303 Viewing data processing unit
311 Distance calculation unit
321 Histogram counting circuit
322 Image data processing unit
PA0 SPAD output pulse
PB0 to PB3 Latch output pulse
SD1 High-speed sampling interval
SD2 Low-speed output interval
601 Smartphone
602 Distance measuring module

1. A distance measuring sensor, comprising:
a single photon avalanche diode (SPAD) pixel including a SPAD as a photoelectric conversion element;
a time-of-flight (ToF) data processing unit that generates and outputs distance measurement data by a ToF method on a basis of a pixel signal output from the SPAD pixel; and
a viewing data processing unit that generates and outputs viewing data on a basis of a pixel signal output from the SPAD pixel.

2. The distance measuring sensor according to claim 1, wherein
the viewing data processing unit counts a number of times the SPAD has reacted within a predetermined measurement period.

3. The distance measuring sensor according to claim 1, further comprising
a mode switching control section that switches a measurement mode, wherein
the mode switching control section switches, in a time division manner, a distance measurement mode in which the ToF data processing unit performs processing and a viewing mode in which the viewing data processing unit performs processing.

4. The distance measuring sensor according to claim 1, further comprising
an output unit that outputs either the distance measurement data from the ToF data processing unit or the viewing data from the viewing data processing unit according to a measurement mode.

5. The distance measuring sensor according to claim 1, wherein
the ToF data processing unit includes
a direct ToF (dToF) data processing unit that generates and outputs the distance measurement data by a direct ToF method, and
an indirect ToF (iToF) data processing unit that generates and outputs the distance measurement data by an indirect ToF method.

6. The distance measuring sensor according to claim 5, further comprising
an output unit that outputs any one of the distance measurement data from the dToF data processing unit, the distance measurement data from the iToF data processing unit, or the viewing data from the viewing data processing unit according to a measurement mode.

7. The distance measuring sensor according to claim 5, wherein
the iToF data processing unit counts a number of times the SPAD has reacted in a first period having a same phase as a light emission timing of irradiation light and a number of times the SPAD has reacted in a second period having a phase obtained by inverting the light emission timing of the irradiation light.

8. The distance measuring sensor according to claim 5, further comprising
a sampling circuit that outputs an n-bit (n>1) sampling result obtained by sampling the pixel signal of one bit output from the SPAD pixel at a first frequency at a second frequency lower than the first frequency.

9. The distance measuring sensor according to claim 8, wherein
a sampling interval at which sampling is performed at the first frequency is a sampling interval in a direct ToF measurement mode,
a light emission interval of irradiation light in an indirect ToF measurement mode is a multiple of the sampling interval of the first frequency, and
an output interval at which the n-bit sampling result is output at the second frequency is same as or a multiple of the light emission interval of the irradiation light in the indirect ToF measurement mode.

10. The distance measuring sensor according to claim 8, wherein
the sampling circuit includes
n first latch circuits that latch the pixel signal of one bit output from the SPAD pixel at the second frequency, and
a second latch circuit that latches outputs of the n first latch circuits at the second frequency to output the n-bit sampling result.

11. The distance measuring sensor according to claim 8, wherein
the dToF data processing unit generates a histogram according to the n-bit sampling result.

12. The distance measuring sensor according to claim 8, wherein
the dToF data processing unit generates a histogram according to a number of cycles until the n-bit sampling result becomes High.

13. The distance measuring sensor according to claim 10, wherein
the iToF data processing unit determines whether the SPAD has reacted in a first period having a same phase as a light emission timing of irradiation light or the SPAD has reacted in a second period having a phase obtained by inverting the light emission timing of the irradiation light according to whether one of the two first latch circuits becomes High first or the other becomes High first.

14. The distance measuring sensor according to claim 10, wherein
the viewing data processing unit counts a number of times of becoming High in one of the first latch circuits.

15. The distance measuring sensor according to claim 5, further comprising:
a latch circuit that latches a count value of n bits (n>1) at a first frequency on a basis of the pixel signal of one bit output from the SPAD pixel; and
a low sampling circuit that outputs a number of cycles and the count value when the pixel signal becomes High at a second frequency lower than the first frequency.

16. The distance measuring sensor according to claim 1, wherein
processing in which the ToF data processing unit generates and outputs the distance measurement data on a basis of the pixel signal output from the SPAD pixel and processing in which the viewing data processing unit generates and outputs the viewing data are simultaneously executed.

17. The distance measuring sensor according to claim 16, wherein
a plurality of the SPAD pixels is arranged in a matrix, and
each of a plurality of the SPAD pixels is provided with a red, green, or blue color filter layer.

18. The distance measuring sensor according to claim 16, wherein
the ToF data processing unit generates a histogram on a basis of the pixel signal output from the SPAD pixel and generates a count mask signal indicating a peak period of the histogram, and
the viewing data processing unit stops counting photons for a predetermined period on a basis of the count mask signal and generates the viewing data.

19. The distance measuring sensor according to claim 16, further comprising
a histogram generation circuit that generates a histogram on a basis of the pixel signal output from the SPAD pixel, wherein
the ToF data processing unit generates a peak section signal indicating a peak section of the histogram on a basis of the histogram supplied from the histogram generation circuit, and
the viewing data processing unit adds data of other than the peak section on a basis of the peak section signal and generates the viewing data.

20. A distance measuring system, comprising:
a light emitting unit that emits irradiation light;
a distance measuring sensor that receives reflected light in which the irradiation light is reflected by an object, wherein
the distance measuring sensor includes:
a single photon avalanche diode (SPAD) pixel including a SPAD as a photoelectric conversion element;
a time-of-flight (ToF) data processing unit that generates and outputs distance measurement data by a ToF method on a basis of a pixel signal output from the SPAD pixel; and
a viewing data processing unit that generates and outputs viewing data on a basis of a pixel signal output from the SPAD pixel.
